(19) United States
(12) Patent Application Publication
(10) Pub. No.: US 2025/0054736 A1
(43) Pub. Date: Feb. 13, 2025

(54) A WAFER CHUCK ASSEMBLY WITH THERMAL INSULATION FOR RF CONNECTIONS

(71) Applicant: Lam Research Corporation, Fremont, CA (US)

(72) Inventors: Patrick G. BREILING, Tigard, OR (US); Sergey G. BELOSTOTSKIY, Sherwood, OR (US); Timothy S. THOMAS, Wilsonville, OR (US); Joel HOLLINGSWORTH, Portland, OR (US); Ramesh CHANDRASEKHARAN, Lake Oswego, OR (US); Mahmoud VAHIDI, Beaverton, OR (US)

(73) Assignee: Lam Research Corporation, Fremont, CA (US)

(21) Appl. No.: 18/723,332

(22) PCT Filed: Jan. 27, 2023
(86) PCT No.: PCT/US2023/061512

§ 371 Date: Jun. 21, 2024

Related U.S. Application Data
(60) Provisional application No. 63/267,423, filed on Feb. 1, 2022.

(51) Int. Cl. H01J 37/32; H01L 21/683

(52) U.S. Cl. CPC H01J 37/32715; H01J 37/32174; H01J 37/32577; H01J 2237/3321; H01J 2237/334; H01L 21/6833

(57) ABSTRACT

Described is a wafer chuck assembly comprising a platen with one or more plasma electrodes, and a radio frequency (RF) assembly comprising at least one RF conductor electrically coupled to the one or more plasma electrodes. The at least one RF conductor comprises a rod with a rod tip coupled to the one or more plasma electrodes, and a rod stem mechanically coupled to a thermal choke with a hollow interior. The rod comprises a first electrically conductive material and has a first width and a first length. The thermal choke comprises a second electrically conductive material, and has a second width and a second length; and the second width is equal or greater than the first width.

### CLAIM FOR PRIORITY

This application claims priority to U.S. Provisional Patent Application No. 63/267,423, filed Feb. 1, 2022 titled “METHOD AND APPARATUS FOR THERMAL INSULATION FOR RF CONNECTIONS,” and which is incorporated by reference in entirety.

### BACKGROUND

Substrate processing systems are used to perform treatments such as deposition and etching of film on substrates such as semiconductor wafers. For example, deposition may be performed to deposit a conductive film, a dielectric film, or other types of film using chemical vapor deposition (CVD), plasma enhanced CVD (PECVD), atomic layer deposition (ALD), plasma enhanced ALD (PEALD), and/or other deposition processes. During deposition, the substrate may be supported in a wafer chuck on a pedestal. Many deposition tools are equipped with components to deliver radio frequency power to electrodes embedded in the pedestal to generate enable sputter deposition of dielectric materials, for example.

Current wafer chuck componentry designs may have potential flaws that may cause premature failure of key parts after the deposition tool has been in service for a short time. Assembly and disassembly procedures of wafer chuck pedestals for servicing and repair may be unduly difficult or risk damage to pedestal components due to suboptimal component design or layout.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A illustrates a cross-sectional view of a radio frequency (RF) assembly, in accordance with at least one embodiment.

FIG. 1B illustrates a cross-sectional view of a wafer chuck assembly comprising the RF assembly shown in FIG. 1A, in accordance with at least one embodiment.

FIG. 1C illustrates a detailed cross-sectional view of the wafer chuck assembly shown in FIG. 1B, in accordance with at least one embodiment.

FIG. 2 illustrates a cross-sectional 1 view of an RF conductor of the RF assembly shown in FIG. 1A, in accordance with at least one embodiment.

FIG. 3A illustrates a plan view of an RF assembly clamp, in accordance with at least one embodiment.

FIG. 3B illustrates a cross-sectional exploded view of the RF assembly clamp shown in FIG. 3A, in accordance with at least one embodiment.

FIG. 3C illustrates a plan view of an alternative embodiment of an RF assembly clamp, in accordance with at least one embodiment.

FIG. 3D illustrates a cross-sectional view of the RF assembly clamp shown in FIG. 3A supporting multiple RF conductors in o-ring retainers, in accordance with at least one embodiment.

FIG. 3E illustrates a. cross-sectional view of a second embodiment of an RF assembly clamp comprising ball and socket retainers, in accordance with at least one embodiment.

FIG. 4 illustrates an exploded 3D cross-sectional view of an adapter tube assembly comprising the RF assembly, in accordance with at least one embodiment.

FIG. 5A illustrates an orthogonal cross-sectional view an wire harness, in accordance with at least one embodiment.

FIG. 5B illustrates a plan view of the wire harness shown in FIG. 5A, in accordance with at least one embodiment.

FIG. 5C illustrates a cross sectional view of an alternative embodiment of the wire hardness shown in FIG. 5A, in accordance with at least one embodiment.

FIG. 6A illustrates a plan view of a spacer plate for separation of RF conductors and heater wires, in accordance with at least one embodiment.

FIG. 6B illustrates a cross-sectional view of the spacer plate of FIG. 6A, in accordance with at least one embodiment.

FIG. 7A illustrates a plan view of an upper clamp ring of a column clamp assembly, in accordance with at least one embodiment.

FIG. 7B illustrates an orthogonal cross-sectional view of the upper clamp ring of FIG. 7A, in accordance with at least one embodiment.

FIG. 8A illustrates a plan view of a lower clamp ring of the column clamp assembly showing an upper surface, in accordance with at least one embodiment.

FIG. 8B illustrates a plan view of the lower clamp ring showing a lower surface, in accordance with at least one embodiment.

FIG. 8C illustrates a cross-sectional view of the lower clamp ring of FIGS. 8A and 8B, in accordance with at least one embodiment.

FIG. 9 illustrates a 3D cross-sectional view of upper wafer chuck assembly, in accordance with at least one embodiment.

FIG. 10 illustrates a semiconductor process tool comprising a wafer chuck assembly as shown in FIG. 1C, in accordance with at least one embodiment.

FIG. 11 illustrates an exemplary flowchart summarizing a method for assembling a wafer chuck assembly, in accordance with at least one embodiment.

### DETAILED DESCRIPTION

In the following description, numerous specific details are set forth, such as structural schemes, to provide a thorough understanding of embodiments of the present disclosure. It will be apparent to one skilled in the art that embodiments of the present disclosure may be practiced without these specific details. In other instances, well-known features, such as gas line tubing fittings, heating elements and snap switches, are described in lesser detail to not unnecessarily obscure embodiments of the present disclosure. Furthermore, it is to be understood that the various embodiments shown in the figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment,” “one embodiment,” “at least one embodiment,” or “some embodiments” means that a particular feature, structure, function, or characteristic described in connection with the embodiment is included in at least one embodiment of the disclosure. Thus, the appearances of the phrase “in an embodiment,” “in one embodiment,” “in at least one embodiment,” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

Terms “over,” “under,” “between,” and “on” may generally refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in claims, a list of items joined by the term “at least one of” or “one or more of” can mean any combination of the listed terms.

Unless otherwise specified in the explicit context of their use, terms “substantially equal,” “substantially identical,” “about equal,” “nearly equal,” and “approximately equal” mean that there is no more than incidental variation between two things so described. In at least one embodiment, incidental variation is typically no more than +/−10% of a referred value or target value. Here, “substantially,” “close,” “approximately,” “near,” and “about,” may generally refer to being within +/−10% of a target value.

Term “adjacent” may generally refer to a position of a thing being next to (e.g., immediately next to or close to with one or more things between them) or adjoining another thing (e.g., abutting it).

In at least one embodiment, a wafer chuck assembly comprising a high temperature (e.g., temperatures above 500° C.) radio frequency (RF) assembly having enhanced thermal and mechanical features is disclosed. In at least one embodiment, RF assembly comprises one or more RF conductor assemblies comprising a metal rod that is welded or brazed to a thermal choke. In at least one embodiment, thermal choke comprises a thin-walled tubular body that is coaxial with the rod to which it is welded. In at least one embodiment, an electrical RF connector may be attached to the base of thermal choke. In at least one embodiment, thermal choke and rod assemblies conduct RF energy to plasma discharge electrodes within wafer chuck. In at least one embodiment, rod is in contact with wafer chuck pedestal platen.

RF conductors may be subjected to high temperatures as they may become heated by contact with the pedestal platen which may be heated to substantially elevated temperatures, for example, above 700° C., to facilitate formation of deposited films. By mechanical contact with heated pedestal, RF conductors may carry substantial heat by conduction down the pedestal column, eventually reaching RF connectors. RF connectors and other components within stem and housing may not tolerate high temperatures. For example, RF connectors may not exceed 150° C. Thermal chokes may significantly restrict heat transfer down rod assembly, protecting the connections. For example, RF conductor rods may have a temperature of 650° C. at their tip, decaying (exponentially) to approximately 500° C. at the junction with the thermal choke. Temperature profile along the thermal choke may decay exponentially from approximately 500° C. to a temperature of less than 150° C. at the attachment point of connector (e.g., at the base of the thermal choke). An insulator sleeve may protect temperature-sensitive components within wafer chuck assembly against heat damage.

In at least one embodiment, thermal choke may have a large length to diameter ratio (e.g., 5:1 or greater) to maximize thermal resistance. In at least one embodiment, thermal resistance of thermal choke may protect the connector attached at the lower end from excessive heat transferred from the platen. In at least one embodiment, a rod may have a substantially shorter length than the thermal choke within the RF conductor assembly. In at least one embodiment, the length of the rod may be limited to effectively maintain an axially uniform temperature. In at least one embodiment, rod comprising a ferromagnetic material such as iron or nickel may be maintained at a temperature above the Curie temperature for lower resistive losses due to magnetic effects on the RF skin depth.

In at least one embodiment, thermal choke may be welded or brazed to a rod to enable enhanced mechanical, electrical and thermal coupling between rod and thermal choke. In at least one embodiment, weld bonded assembly may be an RF conductor having high RF electrical conductance but high thermal resistance. In at least one embodiment, thermal choke may be gold coated to enhance conductivity. In at least one embodiment, RF assembly may further comprise a dielectric sleeve over rod/thermal choke assembly. In at least one embodiment, dielectric sleeve may comprise a ceramic material that thermally and electrically insulates the rod/thermal choke assembly from heat radiated by other rod/thermal choke assemblies. In at least one embodiment, sleeve may also insulate thermally sensitive components lower in pedestal column (further away from heated pedestal) from heat radiated by rods and thermal chokes. In at least one embodiment, RF assembly may be housed within a tubular column coupled to the pedestal.

In at least one embodiment, RF assembly may be housed within an adapter tube as part of a wafer chuck assembly. In at least one embodiment, the wafer chuck assembly may comprise a pedestal stem (integral with pedestal platen) clamped to a flange on an adapter tube. In at least one embodiment, adapter tube comprises features that may enable enhancements to RF assembly in embodiments disclosed herein.

In at least one embodiment, RF assembly comprises a RF assembly clamp assembly that retains multiple RF conductors and constrains lateral and vertical motion of such RF conductors, but permits limited pivotal motion of RF conductors. In at least one embodiment, RF assembly clamp may be located within adapter tube. In at least one embodiment, RF assembly clamp may enable compensation for lateral misalignment of multiple RF conductors with attachment points on wafer pedestal by allowing pivotal motion of RF conductors that are retained by the clamp.

In at least one embodiment, a small lateral misalignment may be present between rod attachment points on pedestal platen (e.g., at locations of plasma electrodes embedded within the platen) and axial centers of RF conductors. In at least one embodiment, such lateral misalignment may produce bending strain of entire RF conductor assemblies comprising rods and thermal chokes, possibly leading to a failure in rod assembly. In at least one embodiment, tolerance of a lateral or vertical displacement of individual rod assemblies may compromise performance of wafer chuck assembly by possible cracking or breakage of RF assemblies. In at least one embodiment, RF rods may be displaced from their points of contact with the wafer pedestal by vibration or thermal expansion. In at least one embodiment, RF assembly clamp may compensate in real time for such displacements.

In at least one embodiment, a column clamp assembly comprising an upper clamp ring and a lower clamp ring is disclosed. In at least one embodiment, column clamp assembly facilitates coupling of a wafer pedestal stem to an adapter tube. In at least one embodiment, the adapter tube comprises a flange at a top portion. In at least one embodiment, pedestal stem comprises a retaining lip. In at least one embodiment, column clamp assembly secures the retaining lip to the flange of the adapter tube. In at least one embodiment, flange of the adapter tube comprises a seating structure (e.g., a groove) for a vacuum seal. In at least one embodiment, the retaining lip compresses the vacuum seal when column clamp assembly is bolted to the flange. In at least one embodiment, an outboard portion of the lower clamp ring is bolted to the flange. In at least one embodiment, an inboard portion of the lower clamp ring is cantilevered to an outboard portion of the lower clamp ring. In at least one embodiment, lower clamp ring is operable to conform to non-planarities of the flange surface by deflecting upward. In at least one embodiment, lower clamp ring comprises a metal alloy or composition (e.g., aluminum) that has a smaller yield stress than the material in the upper clamp ring (e.g., steel). In at least one embodiment, smaller yield stress may enable deflection of lower clamp ring without stressing or damaging adapter tube flange or the adapter tube itself by enabling lower torques on retaining bolts during assemblage of wafer chuck assembly.

Here, “RF assembly” may generally refer to a system comprising an electrically conductive structure operable to conduct radio frequency voltages and currents, such as an assembly comprising a rod and thermal choke. In at least one embodiment, an RF assembly may comprise a thermal choke as part of the electrically conductive structure. In at least one embodiment, an RF assembly may transfer RF power to plasma discharge electrodes, for example.

Here, “RF conductor” may generally refer to a component carrying RF current, such as an assembly comprising a thermal choke and a rod that are mechanically and electrically coupled together. In at least one embodiment, a rod may extend from the thermal choke. In at least one embodiment, a rod and a thermal choke may be coaxial.

Here, “rod” may generally refer to a portion of the electrically conductive structure that is electrically coupled to the thermal choke, such as a tubular or non-tubular rigid component of an RF conductor. In at least one embodiment, a rod may be a solid structure. In at least one embodiment, a rod may comprise a stem portion that is inserted into the hollow interior of the tubular body of a thermal choke.

Here, “tip” or “rod tip” may generally refer to an end of a rod that is distal to the thermal choke in an RF conductor, such as a terminal portion of a rod. In at least one embodiment, a tip may contact plasma generating electrodes within a platen of a wafer chuck assembly.

Here, “rod stem” may generally refer to an end of a rod that is proximal to a thermal choke to which the rod is coupled, such as a portion of the rod that can be inserted into the hollow interior of the thermal choke.

Here, “insertion stop” may generally refer to a ledge above a stem of a rod, such as an widened segment of a rod that acts as an insertion stop to limit length of rod inserted into a thermal choke.

Here, “thermal choke” may generally refer to a tubular structure that retards heat transfer in the axial direction of the tubular structure, such as a hollow tube that is mechanically coupled to a rod. In at least one embodiment, a thermal choke may be a thin-walled tube comprising an electrically conductive material. In at least one embodiment, a wall of the tubular structure may have sufficiently small cross-sectional area to enable a large thermal resistance in the axial direction of the tubular structure.

Here, “tubular body” may generally refer to a tubular structure that is part of a component of an RF assembly, such as a thermal choke. In at least one embodiment, body is tubular as it may be hollow. In at least one embodiment, a tubular body may comprise a cylindrical wall surrounding a hollow interior, and may be referred to as “hollow tubular body.” In at least one embodiment, a thermal choke is an example of a structure comprising a tubular body.

Here, “hollow interior” may generally refer to an interior of a tubular body that is hollow, such as an interior of a thermal choke.

Here, “bond” may generally refer to a joint formed between two or more structures, such as a weld bond or a braze bond. In at least one embodiment, a bond may permanently join the structures.

Here, “weld bond” may generally refer to a welding joint joining two or more metal structures.

Here, “braze bond” may generally refer to a braze joint joining two or more metal structures. In at least one embodiment, braze bond may be defined as an atomic bonding between surfaces of two or more metal structures. In at least one embodiment, braze bond may be formed by reflowing a layer of a low-melting metal (e.g., solder) at an interface of two structures.

Here, “conductive coating” may generally refer to a coating that increases surface conductivity of a conductor, such as a silver or gold coating to enhance surface conductivity of a thermal choke. In at least one embodiment, RF energy travels mostly on the surface of a conductor (e.g., skin effect). In at least one embodiment, a conductive coating may be a thin (e.g., 20 microns or less) coating of gold or other noble metal on an outer wall of a thermal choke to increase surface conductivity.

Here, “electrically conductive” may generally refer to a property of a material to conduct electricity, such as a metal, semimetal or semiconductor.

Here, “electrically non-conductive” may generally refer to a property of a material of non-conduction of electricity, such as a ceramic, glass or non-conductive polymer. In at least one embodiment, many materials that are electrically insulative are also thermally insulative.

Here, “sleeve” may generally refer to a tubular structure comprising a thermally and electrically insulative material, such as an electrically and thermally insulative tubular jacket around a thermal choke. For example, a sleeve may surround a thermal choke as an electrically and thermally insulative jacket. In at least one embodiment, a sleeve may mitigate radiative heat transfer from the thermal choke wall.

Here, “nose” may generally refer to a terminal portion of a sleeve that is tapered inwardly, such as a tapered end of a sleeve. In at least one embodiment, a diameter of a nose is less than a diameter of a sleeve. In at least one embodiment, a nose of a sleeve may guide a sleeve that surrounds a rod into counterbores in a platen of a wafer chuck assembly. In at least one embodiment, counterbores in a platen expose portions of embedded plasma electrodes within a platen and enable a rod tip of RF conductor to contact exposed plasma electrodes.

Here, “electrically conductive material” may generally refer to a material having a property of high electrical conductivity (e.g., 10 mhos or more), such as a metal or doped semiconductor. In at least one embodiment, many electrically conductive materials are also thermally conductive.

Here, “RF assembly clamp” may generally refer to a specialized clamp to retain an RF assembly, such as a clamp comprising a retaining structure. In at least one embodiment, an RF assembly clamp may fit around the thermal choke portion of an RF assembly.

Here, “spacer plate” may generally refer to a plate within the pedestal stem that maintains separation of multiple RF conductors extending from an adapter tube through a pedestal stem to a platen, such as a plate comprising through holes through which RF conductors may pass.

Here, “retaining structure” may generally refer to a part of the RF assembly clamp that may have restricted lateral or pivotal motion to permit small positional corrections to enable self-alignment of an RF assembly, such as a ball retainer or a flexible rim.

Here, “flexible rim” may generally refer to a flexible and/or deformable retaining structure, such as a compliant ring. In at least one embodiment, this structure can be placed around a thermal choke portion of an RF assembly.

Here, “ring” may generally refer to a type of retaining structure. In at least one embodiment, a ring may be an annular structure comprising a compliant material, such as a flexible rim. In at least one embodiment, a ring may comprise an elastomeric material (e.g., rubber. An example of a ring is an o-ring. In at least one embodiment, an o-ring may serve as a flexible rim around an RF assembly within an RF assembly clamp. In at least one embodiment, material of an O-ring may be compliant, permitting an RF assembly to pivot while restraining lateral and vertical motion of RF assembly within an RF assembly clamp.

Here, “elastomeric material” may generally refer to an organic polymeric material, such as rubber, that exhibits a large elastic region in stress-strain space. In at least one embodiment, a large elastic region for an elastomeric material may encompass an elongation strain gₘₐₓ of 100% or greater of its original length or more prior to a yield point, a threshold understood as yield strength or tensile strength, measured as a stress in megapascals (MPa) where the elastomer breaks (some elastomeric materials may have an εₘₐₓ smaller than 100%). This may be compared to a ductile material, such as aluminum, steel, copper, etc., having a strain of 1% (conventionally 0.2% for metals, or 8<0.002) or less prior to its yield point, a threshold measured in MPa, where the material starts to undergo plastic deformation. In at least one embodiment, elastomers, such as most rubber compounds, may undergo macroscopic elastic deformations by straining (e.g., stretching) with relatively low levels of stress. In at least one embodiment, a low level of stress may be 10 MPa of yield strength to cause a strain of greater than 100% for an elastomer, compared to an applied stress of over 200 MPa to stretch a bar of steel by 0.2% of its initial length.

Here, “ball retainer” may generally refer to a specialized retaining structure, such as a ball and socket joint, having a limited rotational motion, allowing small positional corrections of an RF assembly by pivoting the RF assembly for self-alignment.

Here, “aperture” may generally refer to an opening, such as a hole. In at least one embodiment, an aperture may refer to an opening in the retaining structure through which the RF assembly may extend.

Here, “upper portion” and “lower portion” may generally refer to adjacent pieces of an RF assembly clamp, such as a lower clamp ring and an upper clamp ring.

Here, “electrical connector” may generally refer to an electrical connector attached to an RF assembly, such as an RF connector. In at least one embodiment, an electrical connector may be located at the base of the RF assembly.

Here, “threaded barrel” may generally refer to a mobile electrical connector that may mate to a stationary electrical connector attached to the RF assembly, such as connector component that screws onto an electrical connector. In at least one embodiment, a threaded barrel may attach be threading onto a threaded portion of the stationary electrical connector.

Here, “wafer chuck assembly” may generally refer to a structure operable to support a wafer substrate within a processing tool vacuum chamber. In at least one embodiment, a wafer may be a semiconductor wafer supported by a wafer chuck.

Here, “wafer chuck” may generally refer to a structure, such as a pedestal assembly comprising a platen, to hold a wafer for processing, such as an electrostatic chuck (ESC).

Here, “pedestal stem” may generally refer to a portion of a pedestal that extends below a wafer chuck, such as a tube that is mechanically coupled to a wafer chuck. In at least one embodiment, a pedestal stem may have structures that carry electrical conductors and gas lines to a wafer chuck.

Here, “pedestal” may generally refer to a structure that comprises a wafer chuck and a stem attached to the wafer chuck.

Here, “vacuum chamber” may generally refer to a chamber of a processing tool, such as an enclosed space operable to hold a high vacuum (e.g., <<1 torr). In at least one embodiment, a vacuum chamber may provide an evacuated space in which chemical vapor deposition, etching and other processes that require a high vacuum may be conducted.

Here, “platen” may generally refer to a component of a wafer chuck assembly operable to hold a wafer, such as a flat horizontal portion of the wafer chuck. In at least one embodiment, a platen may comprise a clamping mechanism to hold a wafer firmly. In at least one embodiment, a clamping structure may be an electrostatic clamping mechanism, comprising electrodes embedded within the platen, for example, to electrostatically attract a semiconductive wafer. In at least one embodiment, a platen may have temperature control elements embedded within its structure, as well as plasma discharge electrodes for plasma generation.

Here, “RF” may generally refer to radio frequency. In at least one embodiment, radio frequencies in the MHz range, such as radio frequencies ranging between 10 MHz and 100 MHz, may be used in plasma processes.

Here, “radio frequency (RF) power source” may generally refer to a generator of electrical power in the form of radio frequency energy, such as an RF power amplifier coupled to an RF oscillator. In at least one embodiment, a RF power source may be coupled to a RF assembly, as defined herein, to supply RF power (voltage and current) to plasma electrodes within a platen of a wafer chuck assembly.

Here, “column” may generally refer to a tubular housing below a platen, such as the stem of the wafer chuck assembly and adapter tube. In at least one embodiment, a column may house RF assembly and associated components such as RF assembly clamp. In at least one embodiment, a column may comprise a pedestal stem and an adapter tube clamped to the pedestal stem.

Here, “adapter tube” may generally refer to may generally refer to a lower portion of a column portion of a wafer chuck assembly, such as an engineered tubular structure to house an RF assembly. In at least one embodiment, a column portion of a wafer chuck assembly may generally comprise a pedestal stem and an adapter tube clamped to a pedestal stem by a column clamp as defined herein.

Here, “ledge” may generally refer to a shelf or step on a structure, such as an adapter tube flange.

Here, “lip” or “retaining lip” may generally refer to a narrow rim, such as a narrow rim around an end of a pedestal stem of a wafer chuck pedestal. In at least one embodiment, a lip may enable attachment of a pedestal stem to an adapter tube. In at least one embodiment, a retaining lip may serve to compress a vacuum seal seated in a groove within an adapter tube flange.

Here, “vacuum seal” may generally refer to a gasket or compression ring that is compressed within a groove or ledge on a flange, such as an adapter tube flange, to form a tight seal against atmospheric pressure at a joint, such as a joint between a pedestal stem and an adapter tube. In at least one embodiment, a wafer chuck assembly column comprises a pedestal stem and an adapter tube joined together. In at least one embodiment, column may be held under vacuum, thus a vacuum seal may be present at the joint to form a vacuum-tight seal.

Here, “flange” may generally refer to to a wide rim around the end of an adapter tube, such as an adapter tube flange. In at least one embodiment, a flange may comprise bolt holes distributed around the flange for attaching a pedestal stem via a column clamp. In at least one embodiment, bolt holes may be threaded or unthreaded.

Here, “column clamp” may generally refer to a specialized clamp for attaching the column to the adapter tube of wafer chuck assembly, such as a ring clamp secured to an adapter tube flange. In at least one embodiment, a column clamp may comprise two components, for example, an upper clamp ring and a lower clamp ring.

Here, “clamp assembly” may generally refer to a column clamp that comprises multiple parts, such as a column clamp.

Here, “upper clamp ring” and “lower clamp ring” may generally refer to a first component of a column clamp as defined herein. In at least one embodiment, an upper clamp ring may comprise a stiff material such as steel. In at least one embodiment, upper clamp ring may have an annular form factor.

Here, “lower clamp ring” may generally refer to a second component of the column clamp. In at least one embodiment, a lower clamp ring may be below an upper clamp ring in an assembled column clamp. In at least one embodiment, a lower clamp ring comprises two identical pieces that have a semiannular form factor. In at least one embodiment, a lower clamp ring comprises a material that has a smaller stiffness than steel and therefore more compliant, such as aluminum.

Here, “semiannular” may generally refer to a form factor that is half of a ring or annulus structure, such as semiannular segments of a lower clamp ring. In at least one embodiment, an annulus has an outer diameter and an inner diameter.

Here, “semiannular segment” may generally refer to a semicircular half portion (as a stand-alone structure) of a lower clamp ring, where the half portion has a semiannular structure. In at least one embodiment, a lower clamp ring may comprise two semiannular halves that are joined together at ends when assembled.

Here, “beveled portion” may generally refer to a chamfered sidewall, such as a chamfered portion of a sidewall. In at least one embodiment, the upper clamp ring has a beveled portion of an inner sidewall. Here, “chamfered” may refer to a slope or taper. In at least one embodiment, part of a sidewall of an upper clamp ring is chamfered.

Here, “through-hole” may generally refer to apertures or holes in upper and lower clamp rings, such as bolt holes that enable passage of bolts through the through-holes to threaded holes in an adapter tube flange.

Here, “semicircular groove” may generally refer to a groove formed within a semiannular half of a lower clamp ring, such as a groove separating an inboard sidewall and an outboard sidewall. In at least one embodiment, a semicircular groove may have a semicircular shape, as opposed to a straight groove. In at least one embodiment, a semicircular groove may have an inboard sidewall and an outboard sidewall.

Here, “transverse wall” may generally refer to a bottom wall of a groove, such as a semicircular groove as defined herein. In at least one embodiment, a transverse wall may intersect inboard and outboard sidewalls of a semicircular groove.

Here, “outboard” may generally refer to an outer, or peripheral portion of a circular object, such as an annular ring or semiannular structure. In at least one embodiment, a sidewall may be referred to as an “outboard sidewall,” where the sidewall is an outer sidewall of a semiannular structure or annular structure.

Here, “inboard” may generally refer to an inner, or central portion of a circular object, such as a ring. In at least one embodiment, a sidewall may be referred to as an “inboard sidewall,” where the sidewall is an inner sidewall of a semiannular structure or annular structure.

Here, “radius” may generally refer to a distance between a center of a circular or semicircular object and an arc on an object, such as an intermediary distance between an inner diameter and an outer diameter. In at least one embodiment, a radius may be located between an inboard sidewall and an outboard sidewall of a semiannular structure, such as semiannular halves of a lower clamp ring. In at least one embodiment, a radius may fall between inner sidewall and outer sidewall of an annular structure, such as the upper clamp ring.

Here, “oblique angle” may generally refer to an angle that is not a right angle, such as an acute or obtuse angle.

Here, “counterbore” may generally refer to a recessed hole in the bottom of a platen, such as an opening, where a rod of the RF assembly may be inserted. In at least one embodiment, a rod may electrically couple to a plasma discharge electrode within platen.

Here, “plasma discharge electrode” may generally refer to an electrode (or multiple electrodes) embedded within a platen, which are electrically coupled to rod portion of an RF assembly, such as an electrode in contact with an RF conductor.

Here, “contour” may generally refer to a three-dimensional (3D) shape of the inner wall of the adapter tube, such as curved portions of an inner wall of an adapter tube. In at least one embodiment, a 3D shape may comprise circular and non-circular arcs.

Here, “curvature” may generally refer to the curvature of a contour, such as a portion of an inner wall having a varying diameter.

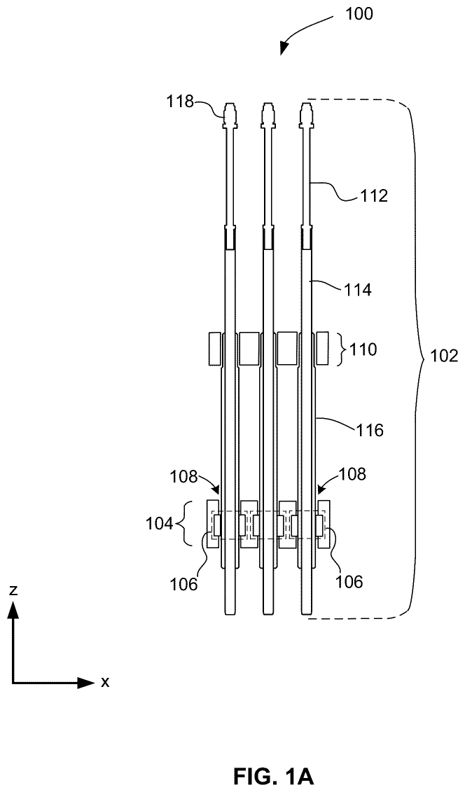

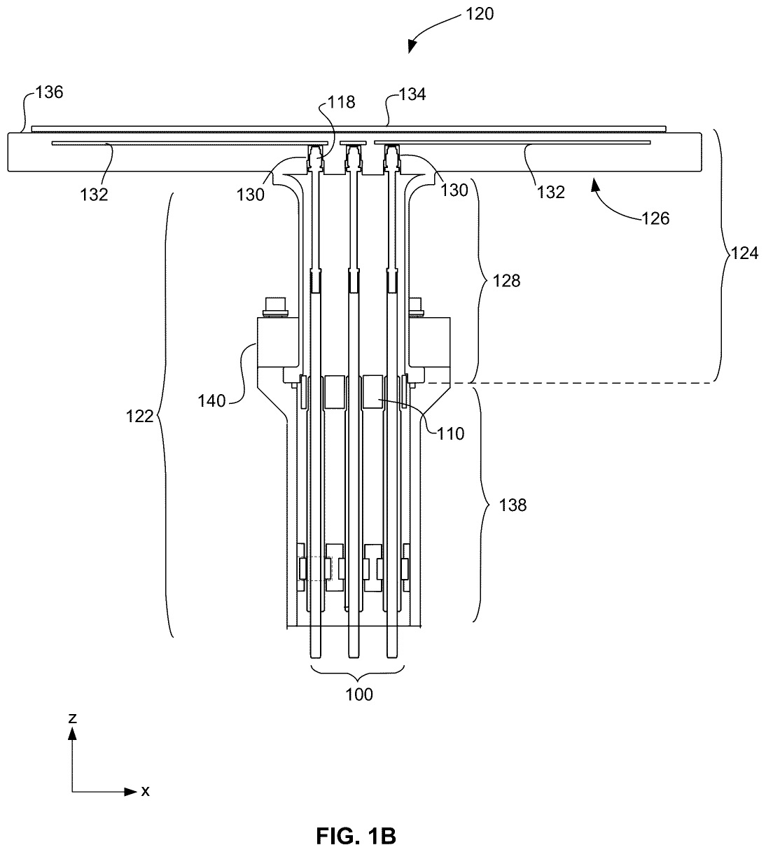

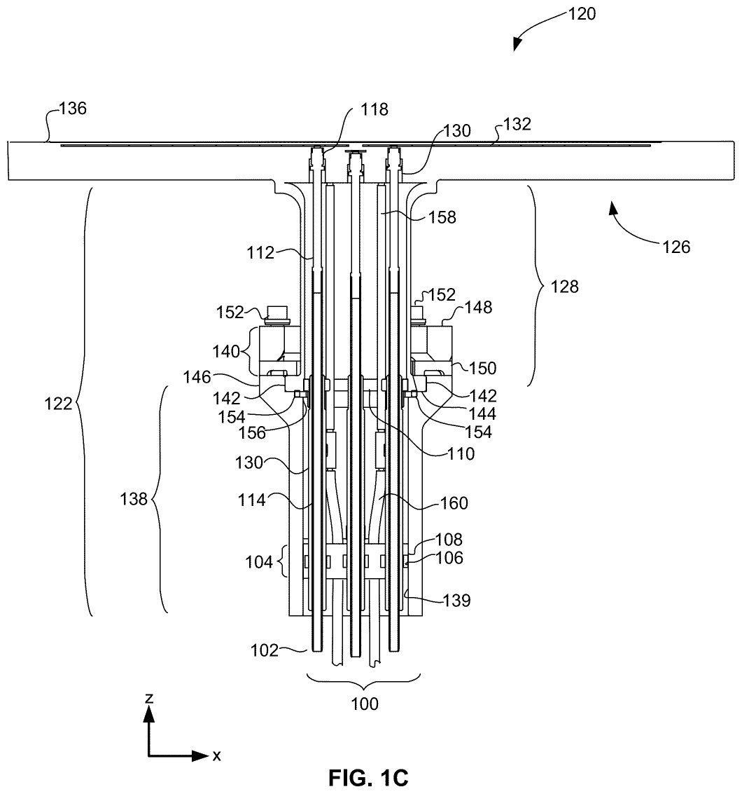

FIG. 1A illustrates a cross-sectional view in the x-z plane of a radio frequency (RF) assembly 100, which is shown as an isolated unit, in at least one embodiment. In at least one embodiment, RF assembly 100 may be implemented within a semiconductor wafer process tool, such as a plasma etch tool or a plasma-enhanced chemical vapor deposition (PECVD) tool. In at least one embodiment, RF assembly 100 may be housed within a wafer chuck pedestal as will be described below (e.g., see FIG. 1B and FIG. 1C).

In at least one embodiment, RF assembly 100 comprises one or more RF conductors, such as RF conductors 102, and an RF assembly clamp 104 mechanically coupled to RF conductors 102. In at least one embodiment, RF assembly clamp 104 includes a retaining structure, such as retaining structure 106, delineated by the dashed box, for each RF conductor 102. In at least one embodiment, retaining structures 106 are internal structures within RF assembly clamp 104. In at least one embodiment, retaining structure 106 comprises one or more apertures 108 through which RF conductors 102 extend. In at least one embodiment, retaining structure 106 is operable to laterally constrain RF conductors 102, but enable limited pivotal motion of RF conductors 102 within RF assembly clamp 104.

In at least one embodiment, spacer plate 110 is included to stabilize RF conductors 102 and maintain a spacing s₁ between RF conductors 102. In at least one embodiment, RF conductors 102 comprise rod 112 mechanically and electrically coupled to thermal choke 114. In at least one embodiment, rod 112 is welded or brazed to thermal choke 114. In at least one embodiment, RF conductors 102 comprise insulating sleeve 116. In some embodiments, sleeve 116 surrounds thermal choke 114, as shown. In at least one embodiment, sleeve 116 may extend to surround rod 112. RF conductors 102 may be operable to handle high RF power (e.g., one to 5 kilowatts). In at least one embodiment, RF conductors 102 may carry RF power to plasma discharge electrodes embedded within a wafer chuck to enable plasma etching or plasma-enhanced deposition processes.

FIG. 1B illustrates a cross-sectional view of wafer chuck assembly 120, comprising RF assembly 100 housed within column 122, in accordance with at least one embodiment. In at least one embodiment, wafer chuck assembly 120 comprises pedestal 124, comprising platen 126 and stem 128 mechanically coupled to and extending below platen 126. In at least one embodiment, stem 128 may be integral with platen 126, as shown. In at least one embodiment, platen 126 may comprise counterbores 130 into which rod tips 118 insert. In at least one embodiment, plasma electrodes 132 may be embedded within platen 126 and positioned above counterbores 130 for electrical coupling to rod tips 118. In at least one embodiment, platen 126 may comprise plasma discharge electrodes (not shown) for electrostatic clamping (ESC) of a wafer substrate 134 on upper surface 136. In at least one embodiment, platen 126 may comprise one or more embedded heating elements (not shown) for desired heating of platen 126 and wafer substrate 134 during an etch or PECVD process. In at least one embodiment, platen 126 may be heated to temperatures exceeding 700° C. during operation.

In at least one embodiment, stem 128 may be mechanically coupled to an adapter tube, such as adapter tube 138. In at least one embodiment, adapter tube 138 may have an interior shape to enable seating of RF conductor 102, as described below. In at least one embodiment, stem 128 is clamped to adapter tube 138 by column clamp assembly 140. In at least one embodiment, column clamp assembly 140 comprises a rigid upper ring and a more elastic ceramic lower ring, as described below. In at least one embodiment, adapter tube 138 may comprise a ceramic material such as, but not limited to, polycrystalline alumina, alumina composites, silica, silicate glasses, aluminum nitride or composites comprising silicates, alumina and/or aluminum nitride.

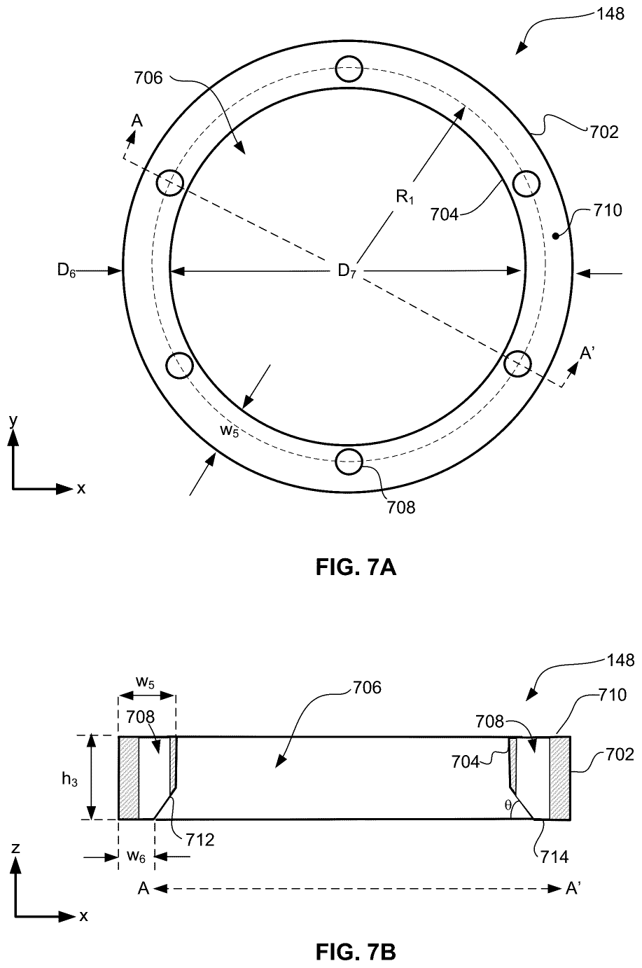

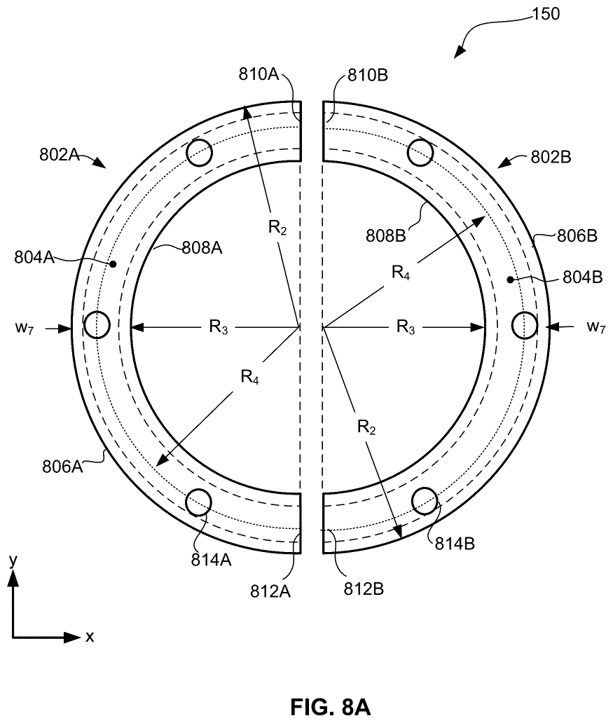

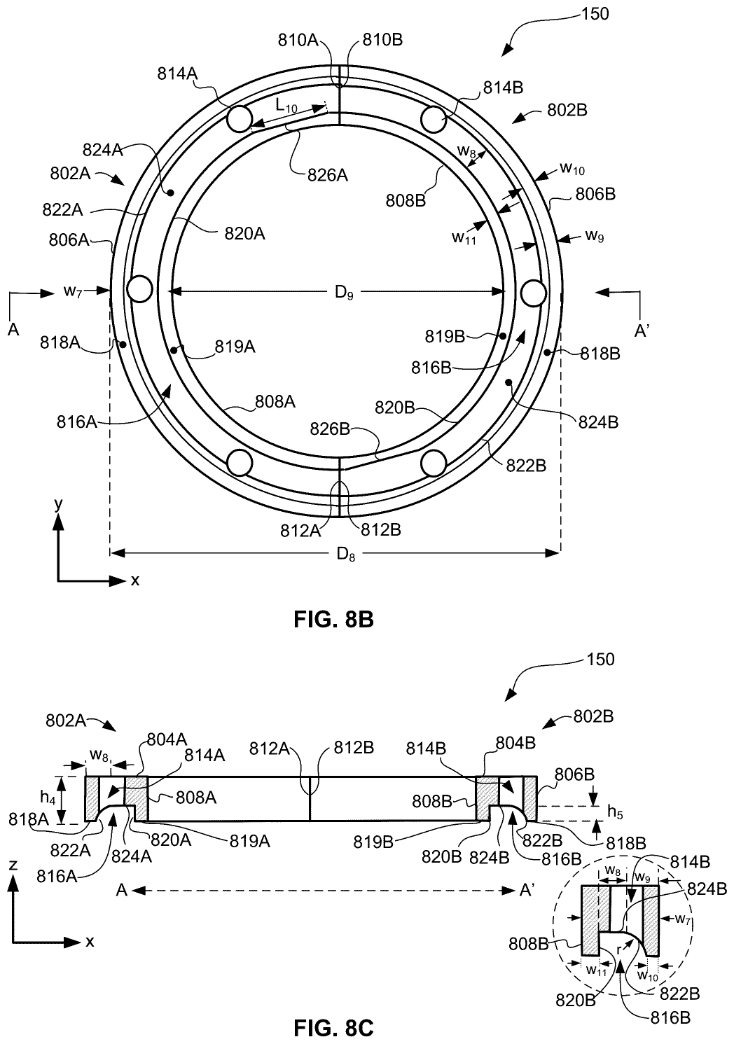

FIG. 1C illustrates a detailed cross-sectional view of wafer chuck assembly 120 comprising RF assembly 100, in accordance with at least one embodiment. In at least one embodiment, stem 128 may be mechanically coupled to adapter tube 138. As shown in FIG. 1C, retaining lip 142 of the stem 128 engages ledge 144 within adapter tube flange 146 when assembled. In at least one embodiment, stem 128 may be secured to adapter tube 138 by column clamp assembly 140, seated on adapter tube flange 146. In at least one embodiment, column clamp assembly 140 comprises upper clamp ring 148 seated on lower clamp ring 150. In at least one embodiment, upper clamp ring 148 may comprise a hardened metal such as, but not limited to, a case-hardened steel alloy or non case-hardened steel alloys. Upper clamp ring 148 is described in greater detail below (see FIGS. 7A and 7B), in accordance with at least one embodiment. In at least one embodiment, lower clamp ring 150 comprises two halves that are assembled together in wafer chuck assembly 120 (e.g., see FIGS. 8A-8C). In at least one embodiment, lower clamp ring 150 may comprise a metallic material having a smaller yield stress than upper clamp ring 148. In at least one embodiment, lower clamp ring 150 may comprise a compliant material such as, but not limited to, aluminum or copper. Column clamp assembly 140 is described in greater detail below (e.g., see FIGS. 7A-7B, 8A-8C), in accordance with at least one embodiment.

In at least one embodiment, upper clamp ring 148 and lower clamp ring 150 are fastened to adapter tube flange 146 by bolts 152. In at least one embodiment, tightening of bolts 152 compresses retaining lip 142 to ledge 144. In at least one embodiment, retaining lip 142 may compress vacuum seal 154 seated on ledge 156. In at least one embodiment, ledge 156 may be countersunk below ledge 144 and adjacent to adapter tube flange 146. In at least one embodiment, vacuum seal 154 may be a ring seal (e.g., an o-ring) comprising a strip of hard elastomer or a malleable metal such as bronze, copper or a steel alloy. In at least one embodiment, vacuum seal 154 may seat within a round or V-shaped groove (not shown) on ledge 156.

In at least one embodiment, bolts 152 may be torqued to ensure adequate pressure on vacuum seal 154 by transferring clamping forces from upper clamp ring 148 to vacuum seal 154 through lower clamp ring 150. In at least one embodiment, lower clamp ring 150 may deform under pressure from upper clamp ring 148. In at least one embodiment, lower clamp ring 150 may deform in such a way as to distribute clamping forces uniformly over retaining lip 142 and vacuum seal 154.

In at least one embodiment, RF assembly 100 may be housed within column 122 of wafer chuck assembly 120. In at least one embodiment, during assembly, RF assembly 100 may be inserted into adapter tube 138. In at least one embodiment, inner wall 139 of adapter tube 138 may have an inner wall that is shaped to orient and position RF assembly 100 within column 122. In at least one embodiment, RF assembly 100 may be inserted into adapter tube 138 to center rod tips 118 within counterbores 130. In at least one embodiment, a spacer plate such as spacer plate 110 may be seated within stem 128 and/or seat on ledge 156 below ledge 144 inside adapter tube flange 146.

In at least one embodiment, spacer plate 110 may comprise apertures or recesses through which RF conductors 102 may pass. In at least one embodiment, spacer plate 110 may stabilize RF conductors 102 in upper portion of column 122. In at least one embodiment, spacer plate 110 may also maintain a spacing s₁ and parallelism between individual RF conductors 102. In at least one embodiment, spacer plate 110 may also comprise additional apertures (described below) for passage of heater conductors 158 extending from heater wires 160 to platen 126.

In at least one embodiment, manufacturing tolerances may induce a mismatch offset between centers of rod tips 118 and counterbores 130. In at least one embodiment, positioning of RF conductors 102 may be at least in part determined by spacing between apertures 108 of RF assembly clamp 104. In at least one embodiment, centering offset may furthermore be caused by or exacerbated by heating cycles of platen 126. In at least one embodiment, RF conductors 102 are also heated to high temperatures during operation of wafer chuck assembly 120.

In implementations where such an offset mismatch is present or potentially induced by platen heating, bending strain may be induced within RF conductors 102. Bending strain may eventually lead to breakage or failure of RF conductors 102. In at least one embodiment, repeated heating to compensate for centering offset between centers of counterbores 130 and centers of apertures 108, retaining structures 106 may be advantageously operable to enable limited pivoting of RF conductors to reduce bending.

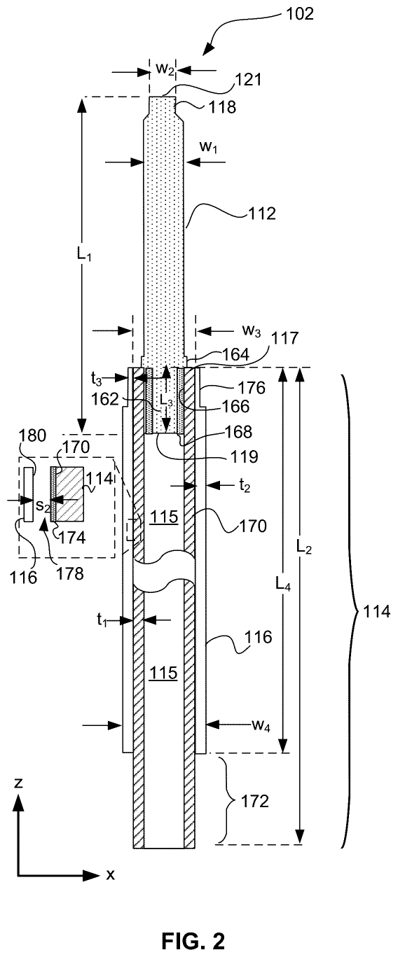

FIG. 2 illustrates a cross-sectional view of RF conductor 102, in accordance with at least one embodiment. In at least one embodiment, RF conductor 102 comprises rod 112 and thermal choke 114 mechanically and electrically coupled to rod 112. In at least one embodiment, rod 112 may be a solid structure, whereas thermal choke 114 may be a tubular structure comprising hollow interior 115. In at least one embodiment, rod 112 may be a coaxial with thermal choke 114.

In at least one embodiment, rod 112 may have an overall length (e.g., from top 121 of tip 118 to base 119) L₁ between 40 and 100 mm. For example, L₁ may be 50 mm. In at least one embodiment, rod 112 may have a width (e.g., diameter) w₁ between 4 and 5 mm. As noted above, rod 112 comprises tip 118 having a width (e.g., diameter) w₂. In at least one embodiment, tip 118 has a structure as shown in FIG. 2, where w₂ is less than w₁ of rod 112. In at least one embodiment, tip may have a different structure, for example as shown in FIG. 1A, where w₂ is equal to or greater than w₁. In at least one embodiment, tip 118 may extend through counterbores 130 in platen 126 to contact plasma electrodes 132 (e.g., see FIGS. 1B and 1C).

In at least one embodiment, width w₂ may be larger than width w₁. For example, width w₂ may range between 5 mm and 7 mm. In at least one embodiment, rod 112 may comprise a conductive material, such as, but not limited to, nickel and nickel alloys, steel alloys, or copper. In at least one embodiment, steel and nickel alloys may magnetize under the influence of RF current flowing in rod 112. In at least one embodiment, ensuing magnetization may degrade electrical conductivity of rod 112. In at least one embodiment, rod 112 may be maintained above Curie temperature of material to mitigate magnetization of rod 112.

In at least one embodiment, thermal choke 114 comprises a tubular body comprising hollow interior 115. In at least one embodiment, thermal choke 114 has an overall length L₂ and a width (e.g., outer diameter) w₃. In at least one embodiment, width w₃ may range between 4 mm and 6 mm. In at least one embodiment, width w₃ is 5 mm. In at least one embodiment, length L₂ may range between 180 and 200 mm. In at least one embodiment, rod 112 may be coupled to thermal choke by insertion of rod stem 162 into hollow interior 115 of thermal choke 114. In at least one embodiment, rod 112 may include insertion stop 164 overhanging rod stem 162 of rod 112, to abut rim 117 of thermal choke 114. In at least one embodiment, insertion stop 164 may be at the top of rod stem 162 a distance L₃ from base 119 of rod stem 162 to limit insertion length L₃ of rod stem 162. In at least one embodiment, length L₁ of rod 112 may be approximately 20% to 50% of length L₂ of thermal choke 114. In at least one embodiment, length L₁ of rod 112 may be determined by the property and temperature of the material of rod 112. In at least one embodiment, length L₁ of rod 112 may be optimized to keep the total length of rod 112 above the Curie point of the material. In at least one embodiment, choice of L₁ may be based on known pedestal temperatures and the thermal conductivity of the rod material.

In at least one embodiment, thermal choke 114 may have a wall thickness t₁ between 1 mm and 2 mm. In at least one embodiment, wall thickness t₁ extends between inner wall 166 and outer wall 170 of thermal choke 114, as shown. In at least one embodiment, wall thickness t₁ may be optimized for maximal thermal resistance in the axial direction (e.g., z-direction of the figure). In at least one embodiment, during operation, heat from platen 126 may be thermally coupled to rod 112 through tip 118 by contact and by radiation, causing heating of rod 112 to significantly elevated temperatures during operation. In at least one embodiment, heat losses from the surface of rod 112 may cause a thermal gradient to be established within rod 112. In at least one embodiment, tip 118 may be heated to 650° C., whereas rod stem 162 at the base of rod 112 may be 500° C. (e.g., for a nickel composition or alloy, rod 112 is above the Curie point of 354° C. for nickel in this example).

In at least one embodiment, length L₃ of rod stem 162, inserted into thermal choke 114, may be limited to a minor fraction of L₁ to limit conductive heat transfer from a heated wafer chuck platen (e.g., platen 126 of wafer chuck assembly 120, FIGS. 1B and 1C), traveling through RF conductor 102 to the base of thermal choke 114. In at least one embodiment, length L₃ may be 10% or less of length L₁ of rod 112 to limit surface area overlap between rod stem 162 and thermal choke 114, thereby mitigating heat transfer (e.g., from heated platen 126) along rod 112 to thermal choke 114. In at least one embodiment, length L₃ of rod stem 162 may be 5% or less of length L₁, further minimizing surface area overlap between rod 112 and thermal choke 114. In at least one embodiment length L₃ of rod stem 162 may be 2% or less of length L₁ to further minimize surface area overlap between rod 112. Minimizing surface area overlap between rod 112 and thermal choke 114 challenges manufacturability/integrity of the RF conductor 102. Smaller surface area overlap makes RF conductor 102 more prone to fracturing when the joint is under high stress (thermal/mechanical stress in assembly and operation). Having L₃ less than 10% of L₁ of rod 112 allows the RF conductor 102 to significantly reduce heat transfer from rod 112 to the base of thermal choke 114 while maintaining its tolerance to thermal/mechanical stress needed for semiconductor fabrication.

In at least one embodiment, mechanical and electrical performance and reliability of RF conductor 102 may be enhanced by integral bonding of rod 112 to thermal choke 114. In at least one embodiment, during assembly of RF conductor 102, rod 112 may be bonded to thermal choke 114 by brazing rod stem 162 to the inner wall 166 of thermal choke 114. In at least one embodiment, a braze bond or weld bond (both types of bonds represented by joint 168) may provide superior mechanical and electrical performance over removable coupling methods, (e.g., such as a collet or a compression fitting).

In at least one embodiment, wall thickness t₁ may also be optimized to provide sufficient tensile strength and stiffness to avoid shape distortion and breakage. In at least one embodiment, an optimal figure of merit for thickness t₁ may be 1 mm. In at least one embodiment, a high-strength alloy as described herein may be employed to enable minimization of wall thickness while maintaining adequate rigidity. In at least one embodiment, thermal choke 114 may comprise a high-strength material such as steel or Inconel alloys. In at least one embodiment, thermal choke 114 may comprise Inconel 625 to withstand high temperatures.

In at least one embodiment, for interfacing additional componentry, such as a wire connector, to RF assembly 100, temperatures below 100° C. to 150° C. may be used at the level of the interface. In at least one embodiment, by optimization of thickness t₁ and length L₂, thermal choke 114 may have sufficient thermal resistance to reduce the temperature from 500° C. at its junction with rod 112 to temperatures tolerable by ancillary components, such as the wire connector (e.g., such as wire harness 500 described below) attached at base 172 of thermal choke 114. In at least one embodiment, the optimization of thickness t₁ and length L₂ may take into account the Young's modulus of the material to determine a minimal wall thickness t₁, for example, to maintain a minimal mechanical strength and stiffness of thermal choke 114. In at least one embodiment, thermal choke 114 may attenuate the rod temperature to under 150° C. at base 172 of thermal choke 114, tolerable by the wire connector.

In at least one embodiment, radio frequency current (e.g., at an RF frequency of approximately 27 MHz) entering RF conductor 102 may travel though the electrically conductive thermal chokes and rods from the connector to electrodes 132 within the platen (e.g., platen 126). In at least one embodiment, RF currents of up to 20 amperes may flow in RF conductors 102. In at least one embodiment, rod 112 may be maintained above the Curie point to avoid magnetically induced skin depth reduction, also enhancing RF conductivity. In at least one embodiment, while high RF currents may cause some Joule heating of RF conductors, the temperature rise resulting from Joule heating may be comparatively small (e.g., up to approximately 50° C.). In at least one embodiment, heat transfer from contact with wafer chuck platen during operation may dominate the temperature profile of RF conductors 102.

In at least one embodiment, thermal choke 114 may comprise a coated or conductive layer 174 on outer wall 170 of thermal choke 114, as shown in the inset of the figure. In at least one embodiment, conductive layer 174 may enhance RF conductivity at the surface. In at least one embodiment, conductive layer 174 may comprise electroplated gold, for example, to enhance RF conductivity. In at least one embodiment, conductive layer 174 may have a thickness ranging between 5 and 20 microns.

In at least one embodiment, while thermal choke 114 may restrict axial heat conduction down the rod assemblies, thermal choke 114 as well as rod 112 may radiate significant heat to surrounding components within the wafer chuck assembly column (e.g., column 122). Heat transfer by convection may be insignificant or non-existent if the pedestal column is under vacuum. Consequently, overheating of nearby components may occur, eventually leading to damage and failure. In at least one embodiment, RF conductor 102 further comprises insulating sleeve 116 (hereafter, sleeve) extending over thermal choke 114 and/or rod 112. In at least one embodiment, sleeve 116 may comprise a dielectric material such as a ceramic or composite ceramic material. In at least one embodiment, the dielectric material may comprise alumina (e.g., aluminum oxide) or aluminum nitride. In at least one embodiment, during operation, sleeve 116 may thermally insulate RF conductor 102. In at least one embodiment, sleeve 116 may inhibit radiative heat transfer from surfaces of RF conductor 102, protecting surrounding temperature sensitive components.

In at least one embodiment, sleeve 116 may further provide electrical insulation for thermal chokes 114 and rods 112. In at least one embodiment, short circuits between adjacent RF conductors or between an RF rod assembly and grounded surfaces may also be prevented by sleeve 116.

In at least one embodiment, sleeve 116 may have a length L₄ that may be substantially equal to at least length L₂ of thermal choke 114. In at least one embodiment, length L₂ may extend at least partially over rod 112, extending up to an additional distance L₁, for example. In at least one embodiment, sleeve 116 has a nominal wall thickness t₂ that may be between 1 mm and 2 mm. In at least one embodiment, sleeve 116 comprises a narrowed wall region at nose 176 at a terminal portion of sleeve 116. For example, nose 176 may have a wall thickness t₃ that may be smaller than thickness t₁. In at least one embodiment, smaller wall thickness t₃ may enable nose 176 to insert into counterbores, such as counterbores 130, within platen 126 (e.g., as described below). In at least one embodiment, sleeve 116 has a width w₄ (e.g., outer diameter, OD) ranging between 7 mm and 8 mm. In at least one embodiment, sleeve 116 may have an inner diameter (ID) of approximately 5 mm. In at least one embodiment, as shown in the inset, gap 178 between inner wall 180 of sleeve 116 and outer wall 170 of thermal choke 114. In at least one embodiment, gap 178 has a spacing s₂ (see inset) that may range between 100 microns and 1 mm. In at least one embodiment, spacing s₂ may be adjusted to accommodate thermal expansion of thermal choke 114.

In at least one embodiment, radio frequency current (e.g., at an RF frequency of approximately 27 MHz) entering the integrated RF socket may travel though the electrically conductive thermal chokes and rods from the connector to plasma discharge electrodes in the platen. In at least one embodiment, RF currents of up to 20 Amperes may flow in RF conductors 102. In at least one embodiment, thermal choke 114 may comprise a conductive layer 174 (e.g., comprising gold) to enhance RF conductivity at the surface, and rod 112 may be maintained above the Curie point of nickel (or other ferromagnetic material) to avoid magnetically induced skin depth reduction, also enhancing RF conductivity. While high RF currents may cause some Joule heating of RF conductors 102, temperature rise resulting from Joule heating may be comparatively small (e.g., up to approximately 50° C.). In at least one embodiment, heat transfer from contact with platen 126 during operation may dominate the temperature profile of RF conductors 102, comprising rod 112 and thermal choke 114.

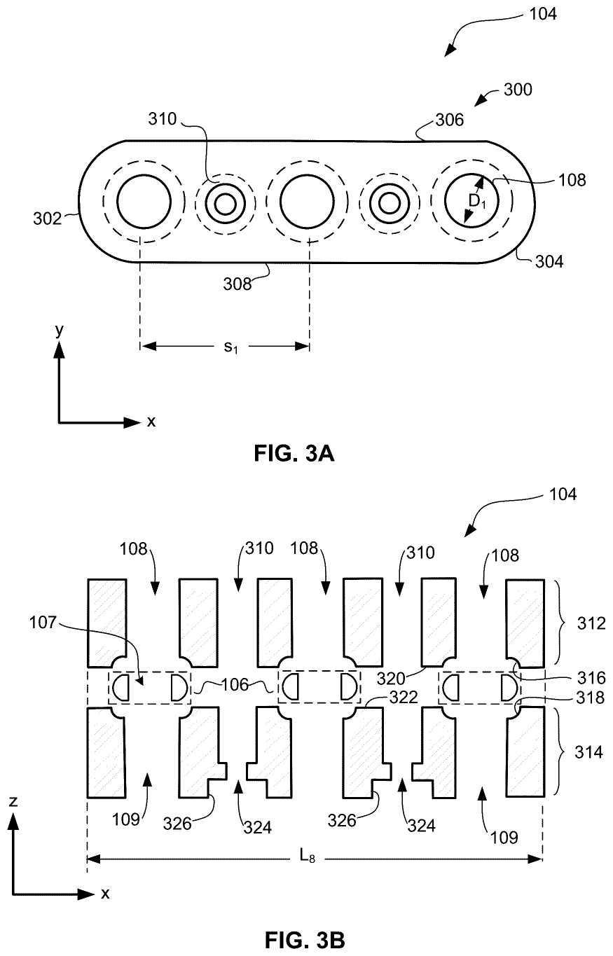

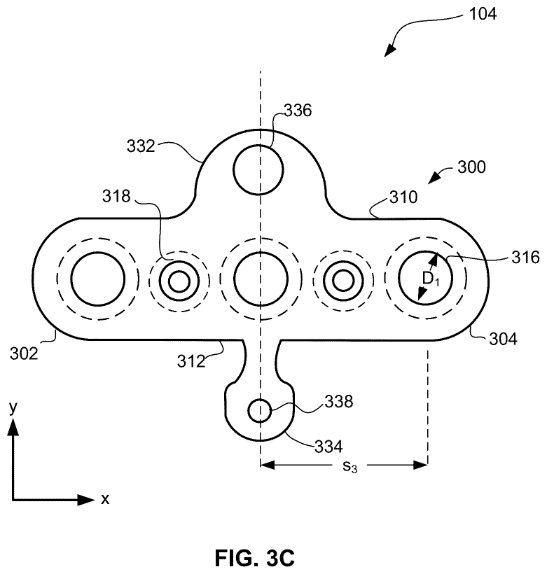

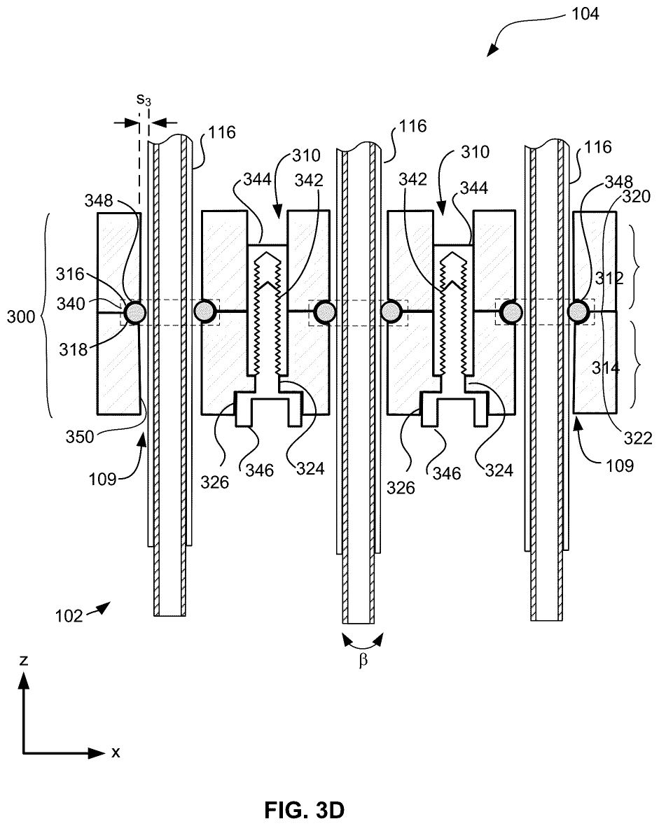

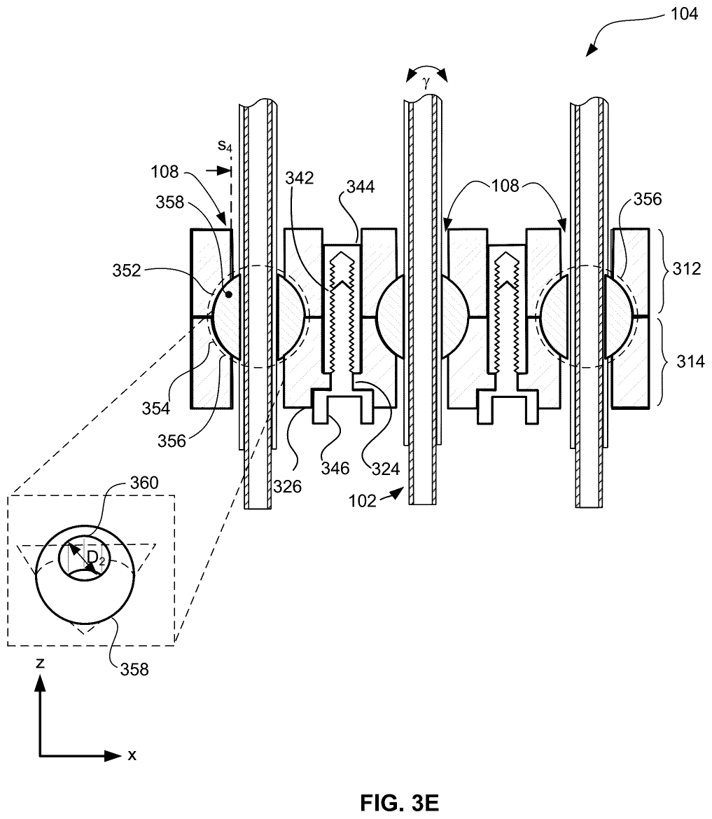

FIG. 3A illustrates a plan view of RF assembly clamp 104, in accordance with at least one embodiment. In at least one embodiment, RF assembly clamp 104 comprises sidewalls 302 and 304, in accordance with at least one embodiment. In at least one embodiment, sidewalls 302 and 304 are straight. In at least one embodiment, sidewalls 302 and 304 may be contoured, for example as shown. In at least one embodiment, sidewalls 306 and 308 may be substantially orthogonal to sidewalls 302 and 304. In at least one embodiment, sidewalls 306 and 308 may be straight as shown, or contoured as will be described below. While a particular shape or curvature of RF assembly clamp 104 is depicted, in at least one embodiment, RF assembly clamp 104 may have any suitable shape. In at least one embodiment, RF assembly clamp 104 may have an asymmetric shape. In at least one embodiment, shape of sidewalls 302 and 304 may facilitate orientation and alignment of RF conductors (e.g., RF conductors 102) with respect to plasma discharge electrodes in the wafer chuck platen (e.g., platen 126).

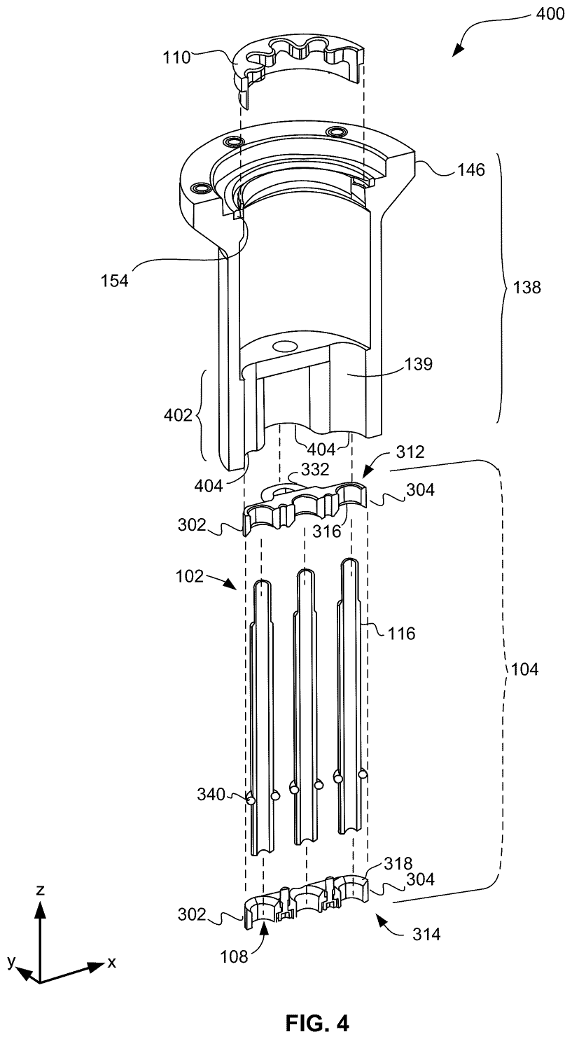

In at least one embodiment, shape asymmetry of RF assembly clamp 104 may enable a keyed orientation of rod assembly clamp when inserted into a wafer chuck assembly (e.g., wafer chuck assembly 120). In at least one embodiment, RF assembly clamp 104 may be inserted into grooves or fit against contours within the adapter tube (e.g., contours of inner wall 139 of adapter tube 138, FIG. 4). In at least one embodiment, RF conductor rod tips (e.g., rod tips 118) may be substantially centered with counterbores in the wafer chuck platen (e.g., platen 126). In at least one embodiment, inner wall of the adapter tube (e.g., inner wall 139) may have an asymmetric contour pattern that is complementary to sidewalls 302 and 304 such that RF assembly clamp 104 may be inserted in a unique orientation.

In at least one embodiment, clamp body 300 comprises an inorganic or organic dielectric material. In at least one embodiment, dielectric material comprises a polymer such as, but not limited to, polyetheretherketone (PEEK), polyimides (e.g., Ultem), polyamide-imide (e.g., Torlon), polyphenylene sulfide (e.g., Ryton, PPS), and blends or composites comprising any of the afore-mentioned polymers. In at least one embodiment, dielectric material comprises a ceramic such as, but not limited to, polycrystalline alumina and silica or silicate glasses.

In at least one embodiment, RF assembly clamp 104 may comprise one or more apertures 108 through which RF conductors (e.g., RF conductors 102) of the RF assembly (e.g., RF assembly 100) may extend. In at least one embodiment, apertures 108 may have a diameter D₁ that may be nominally larger than w₄ of sleeves (e.g., sleeves 116) of the RF conductors. In at least one embodiment, a positive tolerance of diameter D₁ relative to width w₄ may enable RF conductors to pivot to a limited extent (e.g., 5 degrees) within apertures 108. In at least one embodiment, apertures 108 extend through retaining structures, delineated by the dashed circles surrounding apertures 108 (e.g., retaining structures 106, FIG. 1A). In at least one embodiment, retaining structures may constrain lateral movement of RF conductors while allowing limited pivotal motion within apertures 108 for misalignment compensation, as described above.

In at least one embodiment, small pivot angles (e.g., a 5 degree maximum pivot angle, or less) may enable RF conductors to assume a small tilt angle if contact points (e.g., counterbores 130) and centers of apertures 108 are misaligned. In at least one embodiment, a small tilt may mitigate bending of RF conductors that may induce strain, potentially leading to failure.

In at least one embodiment, apertures 108 are equidistant, having a center-to-center spacing s₁ that may be between 1 and 3 cm. In at least one embodiment, spacing s₁ may be substantially equal to the center-to-center spacing between rod tip insertion points (e.g., counterbores 130) in the wafer chuck platen (e.g., platen 126). While in at least one embodiment, one or more apertures 108 are colinear, one or more apertures 108 may also be configured into any suitable non-colinear pattern, in accordance with at least one embodiment. In at least one embodiment, a particular configuration of one or more apertures 108 may mirror the configuration of rod attachment points (e.g., counterbores 130) on the wafer chuck platen to ensure alignment of RF conductors.

In at least one embodiment, RF assembly clamp 104 comprises additional apertures 310 between one or more apertures 108. In at least one embodiment, apertures 310 may be through-holes for fasteners such as screws or bolts.

FIG. 3B illustrates a cross-sectional exploded view of RF assembly clamp 104, comprising upper clamp piece 312 and lower clamp piece 314, in accordance with at least one embodiment. In at least one embodiment, upper grooves 316 and lower grooves 318 may extend around the rims of apertures 108 at upper mating surface 320 and of apertures 109 at lower mating surface 322 of upper clamp piece 312 and lower clamp piece 314, respectively. In at least one embodiment, upper and lower grooves 316 and 318 form a cavity around apertures 108 when upper and lower mating surfaces 320 and 322, respectively, are in contact. In at least one embodiment, cavity may capture retaining structure 106. In at least one embodiment, retaining structure 106 may comprise o-rings as shown in FIG. 3C, or a ball-and-socket joint as shown in FIG. 3D. In at least one embodiment, retaining structure 106 comprises aperture 107 that may be coaxially aligned with apertures 108 and 109.

In at least one embodiment, lower piece 314 may comprise apertures 324 that may be employed as through-holes for fasteners. In at least one embodiment, apertures 324 may align with apertures 310 in upper clamp piece 312 for passage of fasteners, such as bolts, to fasten upper clamp piece 312 to lower clamp piece 314. In at least one embodiment, recesses 326 may provide countersinks for bolt heads, for example.

FIG. 3C illustrates a plan view of an alternate embodiment of RF assembly clamp 104, in accordance with at least one embodiment. In at least one embodiment, RF assembly clamp 104 may be substantially similar to RF assembly clamp 104 shown in FIGS. 3A and 3B. In at least one embodiment, RF assembly clamp 104 comprises front lobe 332 and rear lobe 334. In at least one embodiment, front lobe 332 may comprise aperture 336 for routing of heater wires (e.g., heater wires 160). In at least one embodiment, rear lobe 334 may comprise aperture 338 for passage of a gas purge tube (not shown).

FIG. 3D illustrates a cross-sectional view of an alternative embodiment of RF assembly clamp 104, in accordance with at least one embodiment. In at least one embodiment, RF assembly clamp 104 comprises o-rings 340 (delineated by dashed boxes) as an example of a retaining structure (e.g., retaining structure 106). In at least one embodiment, as shown in FIG. 3B, RF assembly clamp 104 comprises upper clamp piece 312 and lower clamp piece 314. In at least one embodiment, upper and lower clamp pieces 312 and 314 may be fastened together by bolts 342 extending through apertures 310 and 324. In at least one embodiment, bolts 342 may comprise a hex-head 346, for example, seated in recesses 326. Nuts 344 placed within apertures 310 may capture bolts 342 for tightening.

In at least one embodiment, upper and lower circular grooves 316 and 318, respectively, may form upper and lower portions of cavities 348 that may have a torus-like shape around individual one or more apertures 108. In at least one embodiment, o-rings 340 may be seated within cavities 348. In at least one embodiment, o-rings 340 may comprise an elastomeric material that deforms under pressure. In at least one embodiment, when upper piece 312 and lower piece 314 are fastened together, upper and lower grooves 316 and 318 may compress o-rings 340, causing them to bulge a distance beyond sidewalls 350 of one or more apertures 108 to form a constriction within one or more apertures 108.

In at least one embodiment, o-rings 340 may form the constriction about sleeves 116 of RF conductors 102, extending through apertures 108, motion of captured RF conductors may be substantially constrained laterally but permitted rotationally.

In at least one embodiment, RF conductors 102 may undergo limited rotational motion about multiple rotational axes extending within an x-y plane and coinciding with the interface between mating surfaces 320 and 322. In at least one embodiment, a maximal pivot angle β of RF conductors 102 may be at least partly limited by s₃, where s₃ is the width of the gap between sidewalls 350 and sleeves 116 (e.g., D₁−w₄). In at least one embodiment, maximal pivot angle β may be at least partly limited by the elastic deformation of o-rings 340. For example, compression of o-rings 340 may be 10-15%.

FIG. 3E illustrates a cross-sectional view of an alternative embodiment of RF assembly clamp 104, in accordance with at least one embodiment. In at least one embodiment, RF assembly clamp 104 comprises ball retainers 358 (delineated by dashed circles) as an example of a retaining structure (e.g., retaining structure 106). In at least one embodiment, RF assembly clamp 104 comprises upper clamp piece 312 and lower clamp piece 314. In at least one embodiment, upper and lower clamp pieces 312 and 314 may comprise hemispherical grooves 352 and 354, respectively. In at least one embodiment, in an assembled state, hemispherical grooves 352 and 354 combine into a substantially spherical socket 356 (delineated by broken circle), capturing ball retainer 358. In at least one embodiment, ball retainer 358 may rotate freely within spherical socket 356. In at least one embodiment, ball retainer 358 comprises aperture 360 extending through the center of ball retainer 358.

In at least one embodiment, RF conductors 102 are retained by ball retainers 358. In at least one embodiment, RF conductors 102 extend through apertures 360 of ball retainers 358. In at least one embodiment, apertures 360 have a diameter D₂ that may be approximately equal to width w₄ of sleeves 116. In at least one embodiment, diameter D₂ may have a positive tolerance that may be adjusted to provide a tight press fit over sleeves 116. In at least one embodiment, the press fit provided by ball retainers 358 may constrain lateral and vertical motion of RF conductors 102 within apertures 360. In at least one embodiment, ball retainers 358 may comprise an elastomeric material. In at least one embodiment, diameter D₂ may be slightly smaller than width w₄ of sleeve 116. In at least one embodiment, RF conductors 102 may be inserted through apertures 360 and retained, for example, by an interference fit between aperture 360 and sleeve 116.

In at least one embodiment, ball retainers 358 may rotate freely in any direction within socket 356. In at least one embodiment, ball retainers 358 may enable limited rotation of RF conductors 102 within one or more apertures 108 that are fixed. In at least one embodiment, RF conductors 102 may pivot a maximum angle γ that may be limited by distance s₄ between one or more apertures 108 and sleeve 116. In at least one embodiment, maximum angle γ may be optimized to enable alignment between RF conductors 102 and rod insertion points (e.g., counterbore 130) on the wafer chuck assembly platen (e.g., platen 126).

FIG. 4 illustrates an exploded 3D cross-sectional view of adapter tube assembly 400, comprising RF conductors 102 and rod assembly clamp 104 within adapter tube 138, in accordance with at least one embodiment. Dashed lines show approximate alignments of RF conductors (e.g., RF conductors 102) with apertures 108. FIG. 4 shows sleeves 116 of RF conductors. In at least one embodiment, adapter tube 138 comprises inner wall 139 within lower portion 402. In at least one embodiment, inner wall 139 comprises contours 404. In at least one embodiment, contours 404 may have curvatures complementary to curvatures of upper and lower clamp pieces 312 and 314, respectively. In at least one embodiment, contours 404 may conform to the shape of sidewalls 302 and 304, as well as lobe 332. In at least one embodiment, RF assembly clamp 104 may be keyed to a specific orientation within adapter tube 138 by contours 404. In at least one embodiment, at least one of contours 404 may have a substantially different curvature with respect to the other contours to enable keying so that RF assembly clamp 104 may have a unique orientation within adapter tube 138.

In at least one embodiment, RF conductors 102 (e.g., represented by sleeves 116) are shown aligned to apertures 108 of upper and lower clamp body pieces 312 and 314. In at least one embodiment, o-rings 340 surround sleeves 116. In at least one embodiment, o-rings 340 may seat within upper and lower circular grooves 316 and 318, respectively. In at least one embodiment, RF conductors 102 may extend beyond adapter tube flange 146 (e.g., into stem 128 of FIG. 1B). In at least one embodiment, RF assembly clamp 104 may have an orientation enabling RF conductors 102 to align to attachment points on the wafer chuck platen (e.g., platen 126). In at least one embodiment, RF conductors 102 may be further supported and stabilized within adapter tube 138 by spacer plate 110 (e.g., may seat on ledge 156), described below.

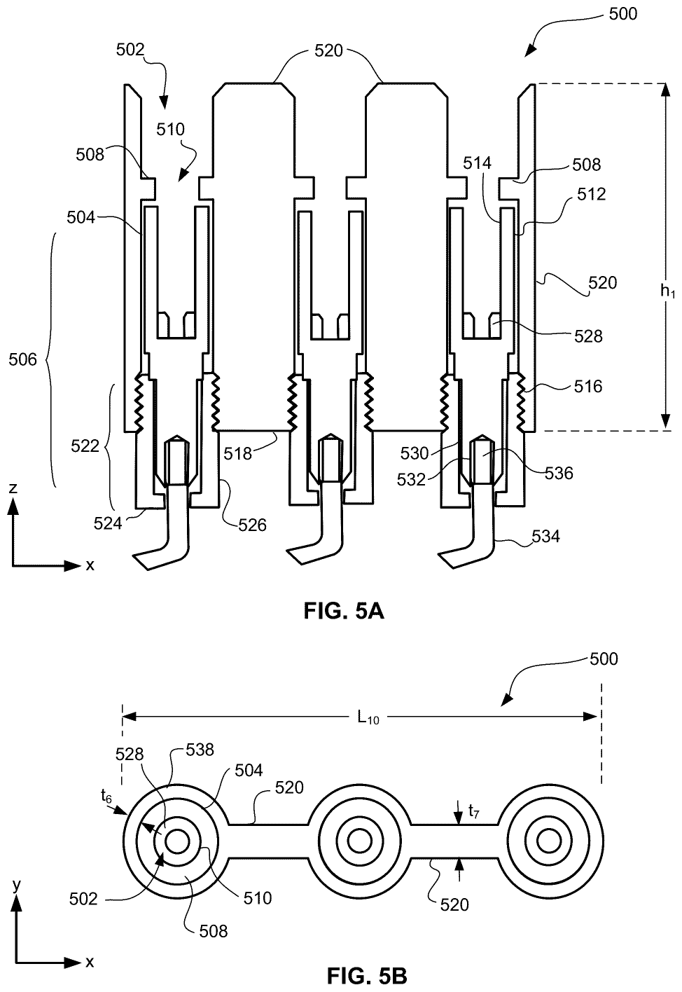

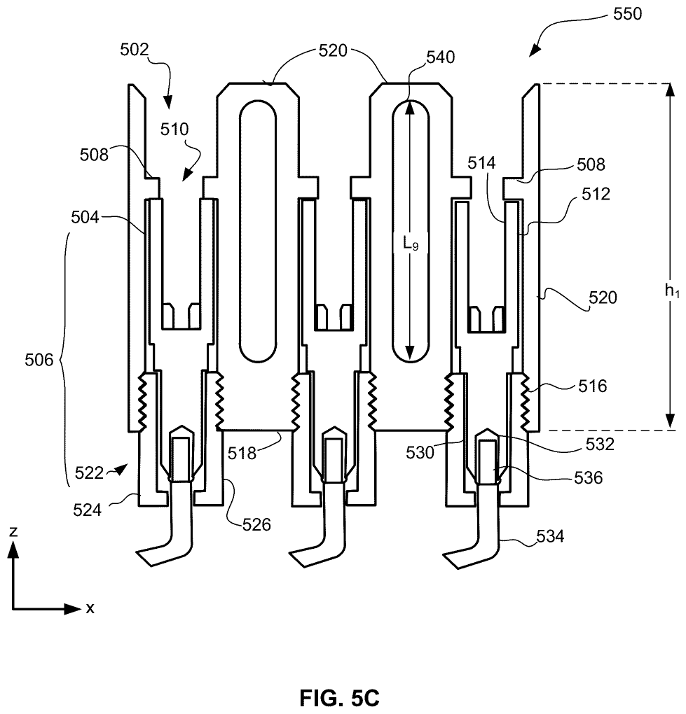

FIG. 5A illustrates a cross-sectional view of wire harness 500, in at least one embodiment. In at least one embodiment, wire harness 500 comprises sleeve wells 502 for seating bottom portions of RF conductor sleeves (e.g., sleeves 116). In at least one embodiment, wire harness 500 comprises connector ports 504 below sleeve wells 502 for seating RF connectors 506. In at least one embodiment, wire harness 500 may comprise a high-temperature polymer such as, but not limited to, PEEK, polyfluorocarbons (e.g., Teflon), polyimides (e.g., Ultem), polyamide-imide (e.g., Torlon), polyphenylene sulfide (e.g., Ryton, PPS), and blends or composites comprising any of the afore-mentioned polymers. In at least one embodiment, sleeve wells 502 and connector ports 504 may be separated by ledge 508. In at least one embodiment, ledge 508 may rim aperture 510. In at least one embodiment, ledge 508 may facilitate alignment of RF conductors 102. In at least one embodiment, thermal choke (e.g., thermal choke 114) of RF connectors 506 may extend through apertures 510 to seat within sockets 512 of RF connectors 506. In at least one embodiment, sockets 512 may have conductive sidewalls 514 for electrical coupling to thermal chokes (e.g., bases 172 of thermal chokes 114).

In at least one embodiment, connector ports 504 comprise an inner threaded portion 516 near bottom sidewall 518 of frame 520. In at least one embodiment, frame 520 interconnects adjacent sleeve wells 502 and connector ports 504. In at least one embodiment, RF connectors 506 comprise threaded barrels 522 comprising an outer thread that mates with inner threaded portion 516. In at least one embodiment, threaded barrels 522 comprise cap 524. In at least one embodiment, cap 524 comprises a hexagonal sidewall 526 having flat sides to facilitate access by a tool (e.g., a wrench) for tightening of threaded barrels 522. In at least one embodiment, RF connectors 506 may be connected or disconnected from RF wire harness 500 by manual turning of threaded barrels 522. In at least one embodiment, tightening of threaded barrels 522 may secure RF connectors 506 within connector ports 504 by pressing RF connector socket 512 against ledge 508. In at least one embodiment, RF connector 506 may be a collet style connector (e.g., an ODU™ Springtac or Lamtac connector). In at least one embodiment, sleeves 116 may pass through apertures 510 to seat within sockets 512. In at least one embodiment, prongs 528 may secure sleeve bases within RF connector sockets 512, also electrically coupling to thermal chokes. In at least one embodiment, RF connectors 506 may comprise stems 530 extending below RF connector sockets 512 into threaded barrels 522. In at least one embodiment, stems 530 may comprise solder wells 532 at the bottom of stems 530. In at least one embodiment, wires 534 may be soldered to stems 530 by insertion of bare ends 536 into solder wells 532 and solder bonded.

FIG. 5B illustrates a top plan view of wire harness 500, comprising walls 538 surrounding sleeve wells 502, in accordance with at least one embodiment. Walls 538 may have a suitable thickness t₆. In at least one embodiment, ledge 508 may comprise aperture 510 between sleeve wells 502 and connector ports 504. In at least one embodiment, prongs 528 may be at the bottom of connector ports 504.

In at least one embodiment, frame 520 may interconnect adjacent sleeve wells 502 and connector ports 504. In at least one embodiment, frame 520 may have a thickness t₇ that may be adjusted to optimize strength and flexibility of RF wire harness 500. In at least one embodiment, wire harness 500 may have an overall length L₁₀ that may be substantially equal to length L₈ of RF rod assembly clamp (e.g., rod assembly clamp 104). In at least one embodiment, wire harness 500 may seat within base of the adapter tube (e.g., adapter tube 138).

FIG. 5C illustrates a cross sectional view of an alternative embodiment of wire hardness 550, in at least one embodiment. In at least one embodiment, frame 520 comprises slots 540 approximately centered between sleeve wells 502. In at least one embodiment, slots 540 may have a length L₉ that may be adjusted to provide flexibility to wire harness 500.

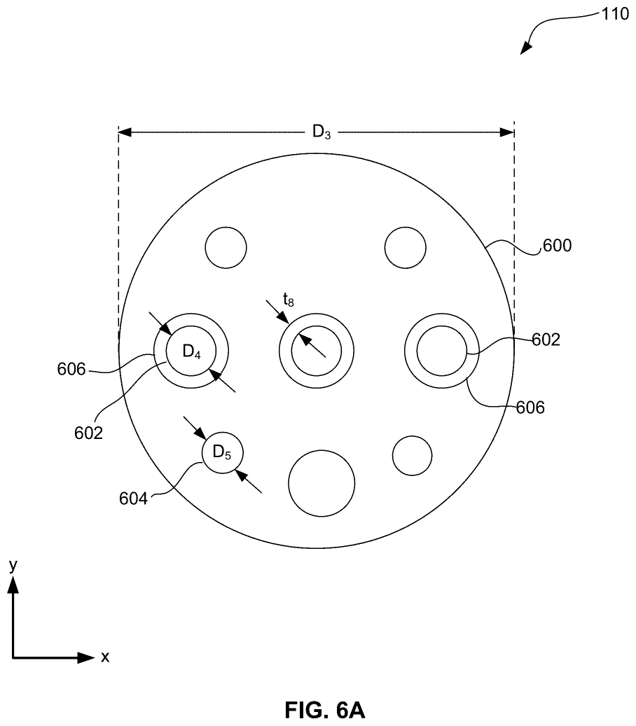

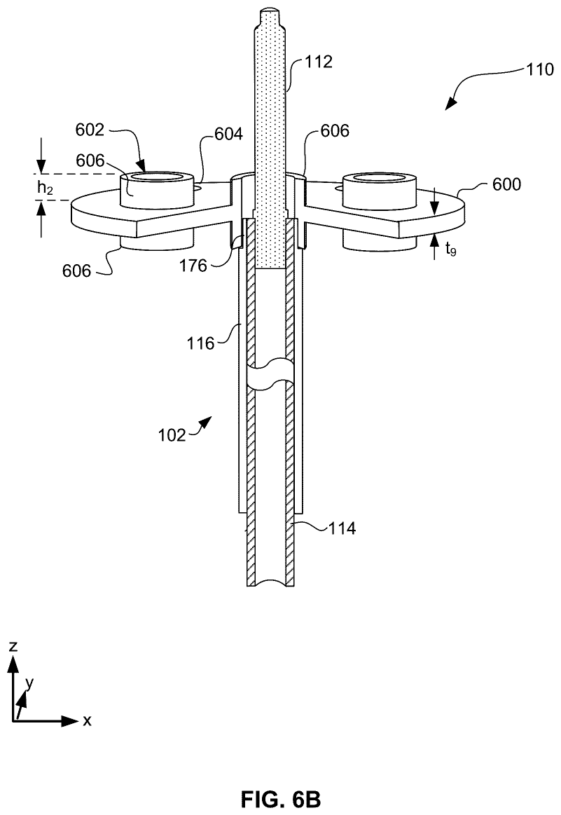

FIG. 6A illustrates a plan view of spacer plate 110, in accordance with at least one embodiment. In at least one embodiment, spacer plate 110 may be substantially disk-shaped, comprising apertures 602 and 604 extending through disk 600 for passage of RF conductors (e.g., RF conductors 102) and heater wires 160 described below. In at least one embodiment, spacer plate 110 may have a diameter D₃ that may be sized to fit within the inner diameter of pedestal stem (e.g., stem 128). In at least one embodiment, diameter D₃ may also be adjusted to enable spacer plate 110 to seat on ledge 156 on the interior of adapter tube flange 146 of adapter tube 138 (e.g., see FIG. 1C). In at least one embodiment, apertures 602 may have a diameter D₄ that may be slightly larger than width w₄ of sleeves 116. In at least one embodiment, offset of apertures 602 may provide adequate clearance for pivotal motion of RF conductors for optimal alignment with contact points on wafer chuck platen (e.g., platen 126).

In at least one embodiment, apertures 604 have a diameter D₅. In at least one embodiment, diameter D₅ may be substantially smaller than diameter D₄ of apertures 602. In at least one embodiment, apertures 604 may permit passage of heater conductors and ESC rods (e.g., heater conductors 158, FIG. 1C) to pedestal stem (e.g., stem 128, FIG. 1C). In at least one embodiment, apertures 602 and 604 may be arranged in any suitable pattern.

In at least one embodiment, spacer plate 110 may comprise a dielectric material such as a ceramic or glass. In at least one embodiment, spacer plate 110 comprises alumina, aluminum nitride, amorphous silica, or silicate glasses. In at least one embodiment, spacer plate 110 provides electrical (and thermal) isolation between rods (e.g., rods 112) and low frequency AC-carrying conductors (e.g., heater conductors 158). In at least one embodiment, spacer plate 110 may also maintain alignment of RF conductors and heater conductors with contact points on the wafer chuck platen.

In at least one embodiment, walls 606 may extend above and below apertures 602 (e.g., as shown in FIG. 6B). In at least one embodiment, walls 606 have a thickness t₈ that may be adjusted for optimal strength of walls 606. In at least one embodiment, walls 606 aid in stabilization of RF conductors.

FIG. 6B illustrates a cross-sectional view of spacer plate 110, in accordance with at least one embodiment. In at least one embodiment, disk 600 has a thickness t₉. In at least one embodiment, thickness t₉ may be sized to optimize strength of spacer plate 110. In at least one embodiment, walls 606 surrounding apertures 602 may extend above and below disk 600 by a height h₂. In at least one embodiment, RF conductor 102 may be engaged with spacer plate 110 by insertion through aperture 602. In at least one embodiment, spacer plate 110 may comprise apertures 602 that may be dimensioned to accommodate a small tilt of the RF conductors.

In at least one embodiment, sleeve nose (e.g., nose 176) may insert in aperture 602 such that a gap is present between the sleeve nose and wall 606. In at least one embodiment, RF conductor 102 may be substantially free to pivot within aperture 602. In at least one embodiment, sleeves of RF conductors may pass completely through apertures 602 and extend to counterbores of the platen.

FIG. 7A illustrates a plan view of upper clamp ring 148 of column clamp assembly 140, in accordance with at least one embodiment. In at least one embodiment, upper clamp ring 148 has an outer diameter D₆, ranging between approximately 7 cm and 15 cm. In at least one embodiment, upper clamp ring 148 comprises outer sidewall 702 and inner sidewall 704. In at least one embodiment, outer sidewall 702 and inner sidewall 704 are separated by distance w₅ (w₅ is also an annular width). In at least one embodiment, inner sidewall 704 surrounds aperture 706, where aperture 706 may have a diameter D₇. In at least one embodiment, upper clamp ring 148 comprises upper surface 710 extending between outer sidewall 702 and inner sidewall 704. In at least one embodiment, outer sidewall 702 and inner sidewall 704 are separated by a width w₅.

In at least one embodiment, upper clamp ring 148 comprises a plurality of through-holes 708 extending through upper surface 710. In at least one embodiment, through-holes 708 are distributed in a symmetrical pattern to provide symmetrical distribution of force imposed by bolts (e.g., bolts 152). For example, upper clamp ring 148 may comprise six evenly spaced through-holes 708. In at least one embodiment, through-holes 708 may enable passage of bolts (e.g., bolts 152, FIG. 1C) to provide clamping force on lower clamp ring 150 (described below).

In at least one embodiment, upper clamp ring 148 comprises upper surface 710 In at least one embodiment, through-holes 708 have a 60-degree azimuthal spacing. In at least one embodiment, centers of through-holes 708 coincide with a radius R₁ that is less than a radius midway between outer diameter D₆ and inner diameter D₇ (e.g., closer to inner diameter D₇. In at least one embodiment, inbound positioning of through-holes 708 enables passage of bolts through a chamfered portion of upper clamp ring 148 (see FIG. 7B). As such, in at least one embodiment, downward force on inbound portions of lower clamp ring 150 is reduced, permitting lower clamp ring 150 to deflect upwardly (described below).

In at least one embodiment, upper clamp ring 148 comprises a metal having a high modulus of elasticity for stiffness. In at least one embodiment, materials such as, but not limited to, steel alloys, tungsten, or titanium may be employed for upper clamp ring 148.

FIG. 7B illustrates an orthogonal cross-sectional view of upper clamp ring 148, in accordance with at least one embodiment. Cross section is taken along cut line A-A′ in FIG. 7A. In at least one embodiment, upper clamp ring has a height h₃ between upper surface 710 and contact surface 714 that may range between approximately 1 cm and 3 cm. In at least one embodiment, inner sidewall 704 comprises bevel 712. In at least one embodiment, bevel 712 reduces the area of contact surface 714 to the outer periphery of upper clamp ring 148. As is described below, inbound portions of lower clamp ring 150 are cantilevered to enable upward deflection so as to conform to non-planarities on adapter tube flange 146 (see FIG. 1C). In at least one embodiment, bevel 712 has an angle θ that may be adjusted to confine contact surface 714 to outboard portions of lower clamp ring 150. In at least one embodiment, angle θ may be adjusted to optimize width w₆ of contact surface 714 in relation to outer diameter D₆. In at least one embodiment, width w₆ may be adjusted to optimize the surface area of contact surface 714 of upper clamp ring 148 for optimal force applied to lower clamp ring 150. In at least one embodiment, width w₆ may be adjusted such that a surface area of upper surface 710 is greater than a surface area of contact surface 714. In at least one embodiment, ratio of areas of upper surface 710 to lower surface 714 may be adjusted to optimize force on lower clamp ring 150, described below.

FIG. 8A illustrates a top plan view of lower clamp ring 150, in accordance with at least one embodiment. In at least one embodiment, lower clamp ring 150 may be a unitary annular structure. In at least one embodiment, lower clamp ring may comprise two mating semiannular halves or segments (referenced as semiannular segment 802A and semiannular segment 802B). In at least one embodiment, semiannular segment 802A is substantially identical to semiannular segment 802B. In at least one embodiment, lower clamp ring comprises aluminum or other suitable metal alloy. In at least one embodiment, semiannular segments 802A and 802B comprise upper surfaces 804A and 804B, respectively, extending between outer sidewalls 806A and 806B, respectively and inner sidewalls 808A and 808B, respectively. In at least one embodiment, width w₇ of semiannular segments 802A and 802B may range between approximately 1 cm and 3 cm. In at least one embodiment, outer sidewalls 806A and 806B extend along outer radius R₂. In at least one embodiment, inner sidewalls 808A and 808B extend along inner radius R₃. In at least one embodiment, semiannular segment 802A and semiannular segment 802B may be joined by abutting end 810A to end 810B, and by abutting end 812A to end 812B (e.g., see FIG. 8B).

In at least one embodiment, semiannular segment 802A comprises a plurality of through-holes 814A. In at least one embodiment, semiannular segment 802B comprises a plurality of through-holes 814B. In at least one embodiment, through-holes 814A and 814B may serve as unthreaded bolt holes to enable passage of bolts from upper clamp ring 148 into adapter tube flange 146, securing stem 128 to adapter tube 138 in wafer chuck assembly 120 (see FIG. 1C).

In at least one embodiment, through-holes 814A and 814B may be evenly distributed along a radius extending through semiannular segments 802A and 802B, respectively. In at least one embodiment, semiannular segments 802A and 802B may each comprise three through-holes 814A and 814B, respectively, which are angularly spaced apart by 60 degrees. In at least one embodiment, centers of through-holes 814A and 814B may be coincidental with a radius R₄. In at least one embodiment, radius R₄ may be more than halfway between outer radius R₂ and inner radius R₃. In at least one embodiment, radius R₄ may be closer to radius R₂ than it is to radius R₃. In at least one embodiment, asymmetric centering of through-holes 814A/B on radius R₄ may enable greater force (e.g., pressure from upper clamp ring 148) on an outboard portion of lower clamp ring 150 relative to an inboard portion of lower clamp ring. In at least one embodiment, an outboard portion of lower clamp ring 150 may be between radius R₄ and outer radius R₂. In at least one embodiment, an inboard portion (e.g., between radius R₄ and inner radius R₃) is cantilevered as this portion is not contacted by upper clamp ring 148. In at least one embodiment, cantilever of an inboard portion of lower clamp ring 150 may enable lower clamp ring 150 to elastically or plastically deform out of plane in order to conform to any non-planarities of adapter tube flange 146. In at least one embodiment, deformation may reduce bending stress on lower clamp ring 150 and adapter tube flange 146 when bolted together in wafer chuck assembly 120 (see FIG. 1C). In at least one embodiment, induced flexure may enable optimal force distribution through lower surfaces 818A, 818B, 819A and 819B by bowing lower clamp ring 150, reducing and displacing contact area to the periphery. In at least one embodiment, metallic materials having a modulus of elasticity that may be lower than that of upper clamp ring 148 may be employed.

In at least one embodiment, material of construction of lower clamp ring 150 may have a low yield strength than material in upper clamp ring 148. The lower yield strength may enable plastic deformation of lower clamp ring 150 at lower levels of mechanical stress (e.g., low bolt torque on upper clamp ring 148) to avoid cracking or otherwise damaging more fragile adapter tube flange 146 and adapter tube 138. In at least one embodiment, adapter tube 138 comprises a ceramic material. In at least one embodiment, lower clamp ring may comprise aluminum (e.g., yield strength of approximately 130 megapascals (MPa), whereas upper clamp ring 148 may comprise a steel alloy (e.g., yield strength of approximately 230 MPa for mild steel).

While lower clamp ring 150 is shown to comprise two semiannular segments, in at least one embodiment, lower clamp ring 150 comprises four quarter-annular segments (not shown). In at least one embodiment, structures such as through-holes 814A and 814B may be distributed in similar or identical configurations on the fourth quarter-annular segments. In at least one embodiment, a first quarter-annular segment comprises a first end and a second end. In at least one embodiment, a second quarter-annular segment comprises a third end and a fourth end. In at least one embodiment, a third quarter-annular segment comprises a fifth end and a sixth end. In at least one embodiment, a fourth quarter-annular segment comprises a seventh end and an eighth end. In at least one embodiment, the second end is adjacent to the third end. In at least one embodiment, the fourth end is adjacent to the fifth end. In at least one embodiment, the sixth end is adjacent to the seventh end. In at least one embodiment, the eighth end is adjacent to the first end.

FIG. 8B illustrates a bottom plan view of lower clamp ring 150, in accordance with at least one embodiment. In at least one embodiment, lower clamp ring 150 may be assembled by abutting end 810A to end 810B and end 812A to 812B, respectively, of semiannular segments 802A and 802B, as shown. In at least one embodiment, end 810A may interlock with end 810B and end 812A may interlock with 812B. For example, end 810A may comprise one or more protruding “key” structures (not shown), such as one or more tabs, tongues, notches or grooves (not shown) extending from ends 810A (not shown), that fit into one or more recessed “lock” regions (not shown) on end 810B to receive the one or more key structures extending from end 810A. In at least one embodiment, recessed regions may have a similar or same shape as the protruding structures, whereby semiannular segments 802A and 802B may interlock by fitting protruding structures into recessed regions in a key and lock fashion. In at least one embodiment, ends 810A may comprise protruding pins, whereas ends 810B may comprise holes into which protruding pins insert to cause semiannular segments 802A and 802B to interlock.

Lower clamp ring 150 may comprise semiannular segments 802A and 802B to facilitate assembly of wafer chuck assembly 120, For example, semiannular segments 802A and 802B may be inserted between upper clamp ring 148 and adapter tube flange 146 and abutted together. When assembled, lower clamp ring 150 may have an outer diameter D₈ (e.g., sum of radii R₂) and inner diameter D₉ (e.g., sum of radii R₃).

In at least one embodiment, groove 816A and groove 816B extend along circular arcs on lower faces of semiannular segments 802A and 802B, respectively, between outer sidewalls 806A and 806B and inner sidewalls 808A and 808B. In at least one embodiment, grooves 816A/B extend between lower surfaces 818A/B and 819A/B, respectively. In at least one embodiment, lower surfaces 818A and 818B are substantially planar and parallel to upper surfaces 804A and 804B. In at least one embodiment, grooves 816A and 816B may combine to form a continuous circular groove when lower clamp ring 150 is assembled.

In at least one embodiment, grooves 816A and 816B comprise inboard sidewall 820A and inboard sidewall 820B, respectively, as well as outboard sidewall 822A and outboard sidewall 822B, respectively. In at least one embodiment, outboard sidewalls 822A/B are curved or linearly tapered, as described below, (e.g., shown in cross-section in FIG. 8C). In at least one embodiment, grooves 816A and 816B may include transverse wall 824A and transverse wall 824B that extend between inboard sidewalls 820A and 820B and outboard sidewalls 822A and 822B. In at least one embodiment, transverse walls 824A and 824B are substantially orthogonal to inboard sidewalls 820A and 820B, forming an abrupt intersection with inboard sidewalls 820A and 820B. In at least one embodiment, transverse walls 824A/B may have linearly tapered or curved intersections with outboard sidewalls 822A and 822B, respectively.

In at least one embodiment, grooves 816A and 816B may have a width w₈ that excludes a maximum taper width w₉ of outboard sidewalls 822A/B. In at least one embodiment, maximum taper width w₉ of outboard sidewalls 822A and 822B may be adjusted to enable a desired cantilever deflection of transverse walls 824A/B. In at least one embodiment, widths w₁₀ and w₁₁ of lower surfaces 818A/B and 819A/B, respectively, may also be adjusted for optimal force distribution on interfacing surfaces, as described below.

In at least one embodiment, inboard sidewalls 820A/B may include flat portion 826A and flat portion 826B, respectively. In at least one embodiment, the position and length L₁₀ of flat portions 826A/B may be adjusted to abut guide structures that may be present on adapter tube flange 146. Such guide structures may orient and/or facilitate centering of lower clamp ring 150 on adapter tube flange 146.

In at least one embodiment, overall width w₇ of semiannular segments 802A/B may be adjusted to undergo a desired cantilever deflection when a normal force is exerted on lower surfaces 819A and 819B. In at least one embodiment, width w₇ may be adjusted for optimal distribution of force applied on adjacent interfacing surfaces (e.g., retaining lip 142 and adapter tube flange 146) for optimal thermal-mechanical performance of column clamp assembly 140.

FIG. 8C illustrates an orthogonal cross-sectional view of lower clamp ring 150, taken along cut line A-A′, shown in FIG. 8B, in accordance with at least one embodiment. In at least one embodiment, lower clamp ring 150 comprises assembled semiannular segments 802A and 802B adjoined at abutted ends 812A and 812B, respectively. In at least one embodiment, lower clamp ring 150 has a thickness h₄. In at least one embodiment, thickness h₄ ranges between approximately 0.5 and 2 cm. In at least one embodiment, transverse walls 824A/B may be recessed by a depth h₅ below lower surfaces 818A/B and 819A/B, respectively. In at least one embodiment, h₅ is the depth of grooves 816A/B. In at least one embodiment, depth h₅ may range between 0.5 cm to approximately 75% of thickness h₄. In at least one embodiment, depth h₅ may be adjusted for optimal performance of lower clamp ring 150. In at least one embodiment, adjustment may depend on material, width w₇, and any vertical offset between lower surfaces 818A/B and 819A/B (in at least one embodiment, lower surfaces 818A/B and 819A/B are shown to have substantially zero vertical offset). In at least one embodiment, depth h₅ may be optimized to enable cantilevered portion of lower clamp ring 150 to bend at a desired clamp force on upper surfaces 808A/B to conform to non-planarities of adapter tube flange 146. In at least one embodiment, deformation of lower clamp ring 150 may prevent damage to adapter tube flange 146 and adapter tube 138 (see FIG. 1C) distributed between lower surfaces 818A/B and 819A/B, respectively.

In at least one embodiment, outboard sidewalls 822A/B may have a widening taper approaching transverse walls 824A/B, respectively, as noted above. In at least one embodiment, outboard sidewalls 822A/B may asymptotically blend with transverse walls 824A/B, forming a rounded (curved) or linearly tapered intersection. For example, in at least one embodiment, the intersection between outboard sidewalls 822A/B and transverse walls 824A/B is rounded, having a non-zero radius of curvature r, as shown in the inset. In at least one embodiment, a linearly tapered or curved intersection may provide a reinforced joint that can enable transverse walls 824A/B to be cantilevered from outboard sidewalls 822A/B.

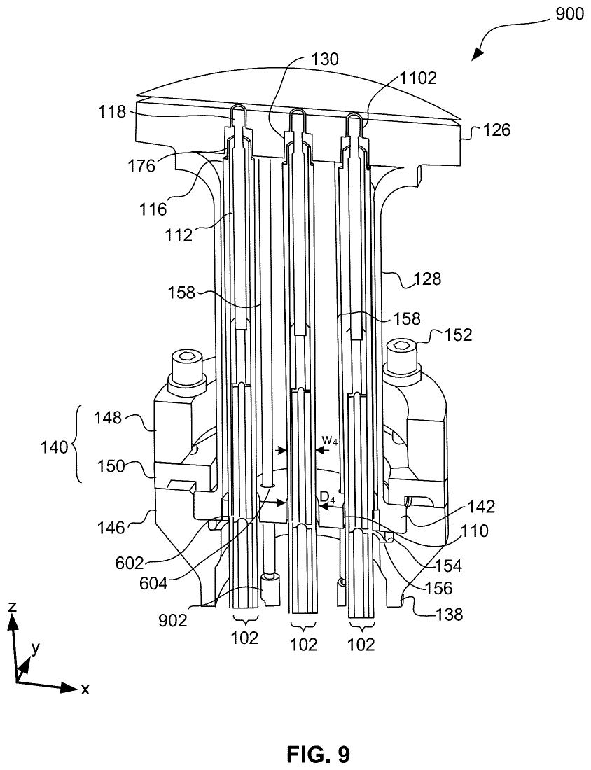

FIG. 9 illustrates a 3D cross-sectional view of upper wafer chuck assembly 900, in accordance with at least one embodiment. In at least one embodiment, upper wafer chuck assembly 900 may extend between platen 126 and the upper portion of adapter tube 138. In at least one embodiment, RF conductors 102 may extend from the lower portion of adapter tube 138 to platen 126 at the top of stem 128. In at least one embodiment, sleeves 116 may extend over almost the entire length of rods 112 to provide thermal insulation for rod temperature regulation. In at least one embodiment, tips 118 of rods 112 may extend above noses 176 of sleeves 116. In at least one embodiment, tips 118 of rods 112 may seat within counterbores 130. In at least one embodiment, tips 118 may attach to plasma discharge electrodes within platen 126 (not shown), located above counterbores 130. In at least one embodiment, noses 176 may seat within counterbores 130 at the bottom surface of platen 126 to align RF conductors 102. In at least one embodiment, counterbores 130 may be dimensioned to permit clearance for pivotal motion of RF conductors 102.

In at least one embodiment, spacer plate 110 may seat within base of stem 128 inside of retaining lip 142. In at least one embodiment, RF conductors 102 may pass through apertures 602 in spacer plate 110. In at least one embodiment, diameter D₄ of apertures 602 may be adjusted for clearance between width w₄ of sleeves 116 and diameter D₄ of apertures 602. In at least one embodiment, clearance may enable pivot of RF conductors 102 and accommodate thermal expansion of sleeves 116. In at least one embodiment, heater conductors 158 may extend from wire attachment lugs 902 (e.g., extending from heater wires 160 in lower portion of adapter tube 138) below spacer plate 110. In at least one embodiment, heater conductors 158 may extend into stem 128 through apertures 604. In at least one embodiment, heater conductors 158 may attach to heating elements in platen 126 (connections not shown). In at least one embodiment, spacer plate 110 may provide electrical and thermal insulation between sleeves 116 and heater conductors 158.

In at least one embodiment, stem 128 may be attached to adapter tube 138 by column clamp assembly 140 comprising upper clamp ring 148 and lower clamp ring 150. In at least one embodiment, clamping force from tightened bolts 152 may be transferred through column clamp assembly 140 to retaining lip 142 to compress vacuum seal 154 against ledge 156. In at least one embodiment, upper and lower clamp rings 148 and 150, respectively, may distribute forces such that compression of vacuum seal 154 is uniform. In at least one embodiment, vacuum seal 154 may be engineered as a high vacuum or ultra-high vacuum seal.

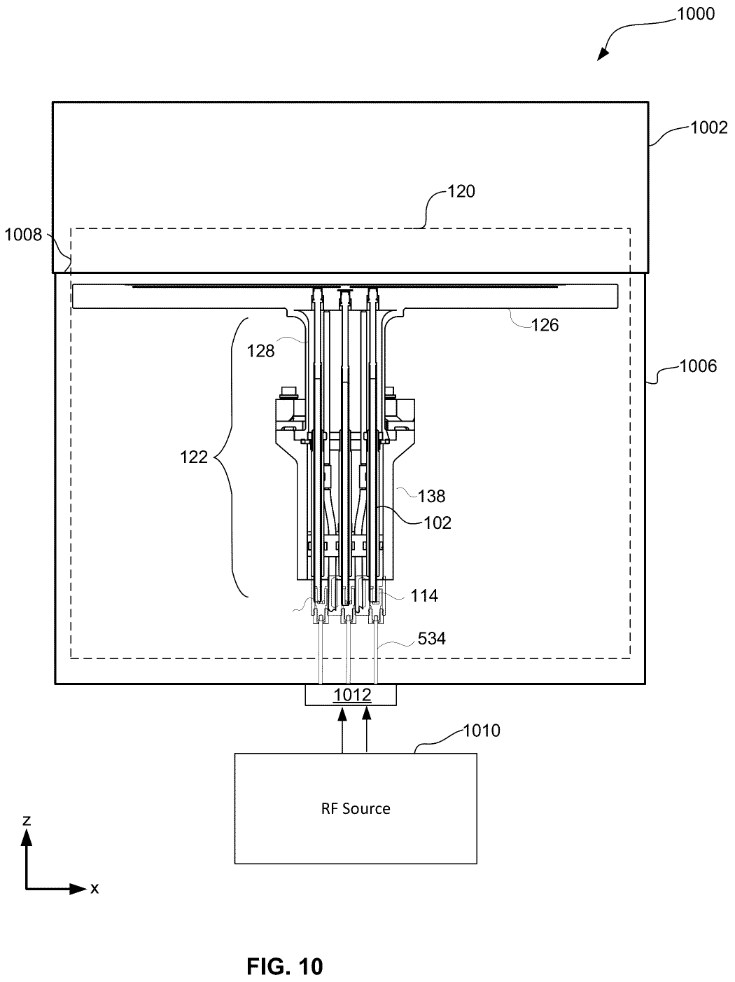

FIG. 10 illustrates a semiconductor process tool 1000 comprising wafer chuck assembly 120, delineated by the dashed box, in accordance with at least one embodiment. In at least one embodiment, semiconductor process tool 1000 may be wafer process tool, such as, but not limited to, a plasma-enhanced chemical vapor deposition (PECVD) apparatus, an atomic layer deposition apparatus, an RF sputtering apparatus, a dry etch apparatus, or a plasma cleaning apparatus. In at least one embodiment, wafer chuck assembly 120 comprising platen 126 may be housed within vacuum chamber 1002. In at least one embodiment, vacuum chamber 1002 may be a high vacuum chamber or an ultrahigh vacuum chamber. In at least one embodiment, column 122 comprising stem 128 and adapter tube 138 may be housed within cabinet 1006 below vacuum chamber 1002. In at least one embodiment, platen 126 may be on top surface 1008 of cabinet 1006, as shown. In at least one embodiment, platen 126 may be recessed below top surface 1008 (not shown). In at least one embodiment, cabinet 1006 may be under vacuum during operation of semiconductor process tool 1000.

In at least one embodiment, RF conductors 102 are connected to RF power source 1010 by wires 534 attached to feedthrough connector 1012. In at least one embodiment, feedthrough connector 1012 may split the RF power from a coaxial cable running from RF power source 1010. In at least one embodiment, RF power may be coupled into thermal chokes 114 through wire harness 500.

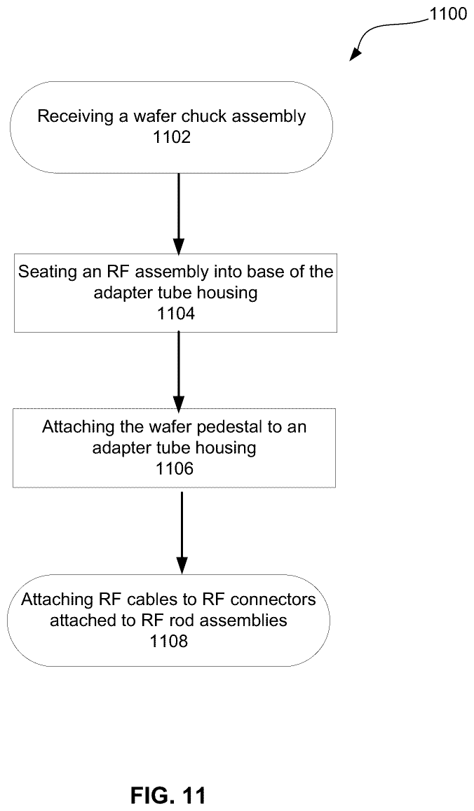

FIG. 11 illustrates an exemplary flowchart 1100 summarizing a method for assembling a wafer chuck assembly (e.g., wafer chuck assembly 120), in accordance with at least one embodiment. In at least one embodiment, flowchart 1100 starts at operation 1102. In at least one embodiment, a wafer chuck pedestal assembly may be prepared for assembly. In at least one embodiment, wafer chuck pedestal assembly may comprise a pedestal platen (e.g., platen 126) and an integral pedestal stem (e.g., stem 128). In at least one embodiment, an adapter tube housing may also be prepared for incorporation into wafer chuck pedestal.

In at least one embodiment, at operation 1104, an RF assembly comprising one or more RF conductors (e.g., RF conductors 102) clamped within an RF assembly clamp (e.g., RF assembly clamp 104) may be inserted into base of adapter tube housing. In at least one embodiment, the body of RF assembly clamp comprises contours (e.g., sidewalls 302, 304) that match contours on an interior wall of adapter tube (e.g., of inner wall 139 and contours 404) of adapter tube (e.g., adapter tube 138). In at least one embodiment, RF rod assembly clamp may have an asymmetric shape so that it may be inserted in a unique (e.g., keyed) orientation. In at least one embodiment, contours 404 may have a corresponding asymmetry with respect to one another so that RF assembly clamp 104 may be inserted in the keyed orientation. In at least one embodiment, keyed orientation may ensure alignment of RF conductors to contact points on pedestal platen (e.g., counterbores 130) when adapter tube housing is attached to pedestal stem as described below.

In at least one embodiment, individual RF conductors may comprise an electrically conductive rod (e.g., rod 112) integrally bonded (e.g., welded) to an electrically conductive thermal choke (e.g., thermal choke 114). RF conductors have been described above, in accordance with at least one embodiment. In at least one embodiment, integral structure comprising rod and thermal choke may be insulated by a dielectric cylindrical sleeve (e.g., sleeve 116). In at least one embodiment, insulating sleeve may provide both thermal and electrical insulation for the rod/thermal choke structure. In at least one embodiment, RF conductors may further comprise an RF electrical connector (e.g., wire harness 500) attached to base portions (e.g., bases 172) of the thermal chokes.

In at least one embodiment, RF conductors may be constrained within RF rod assembly clamp by deformable o-rings stretched around the dielectric sleeves. In at least one embodiment, o-rings may permit a rocking or pivotal motion of RF conductors to correct for misalignment of rods with contact points (e.g., counterbore 130) on bottom of pedestal platen. In at least one embodiment, RF conductors may be retained within ball retainers captured within spherical sockets in body of RF rod assembly clamp. In at least one embodiment, ball-and-socket joints may be rotatable, enabling limited pivotal motion of RF conductors while constraining lateral and vertical motion.

In at least one embodiment, at operation 1106, wafer chuck pedestal may be attached to adapter tube housing. In at least one embodiment, pedestal stem may comprise a lip (e.g., retaining lip 142) at its base that seats onto a ledge (e.g., ledge 144) within top end of the adapter tube housing. In at least one embodiment, during assembly procedure, top end of adapter tube housing may be approached to base of pedestal stem. In at least one embodiment, individual RF conductors may be inserted through apertures within a spacer plate (e.g., apertures 602 in spacer plate 110) seated within base of pedestal stem. In at least one embodiment, spacer plate 110 may be seated on a ledge inside of lip of pedestal stem.

In at least one embodiment, base of the pedestal stem may be inserted into top end of adapter tube housing. In at least one embodiment, once pedestal stem is inserted into adapter tube housing, a clamp (e.g., column clamp assembly 140) comprising an upper clamp ring (e.g., upper clamp ring 148) and a lower clamp ring (e.g., lower clamp ring 150) may be bolted to adapter tube flange (e.g., adapter tube flange 146). In at least one embodiment, lower clamp ring straddles flange and pedestal stem lip. In at least one embodiment, lower clamp ring comprises a material that has sufficient elasticity to deform slightly and distribute clamping forces transferred by upper clamp ring by torquing down multiple clamp bolts (e.g., bolts 152).

In at least one embodiment, at operation 1108, RF connections may be made to wafer chuck pedestal assembly. In at least one embodiment, a wire harness (e.g., wire harness 500) comprising a dielectric (e.g., PEEK) body may be inserted into base of adapter tube housing. In at least one embodiment, wire harness may have a contoured body that fits into contoured recesses (e.g., contours 404) of interior wall of adapter tube housing. In at least one embodiment, RF connectors (e.g., RF connectors 506 may be inserted into connector ports (e.g., connector ports 504) of wire harness. In at least one embodiment, wire harness may be inserted over RF conductors. In at least one embodiment, dielectric sleeves of RF conductors may seat within wells (e.g., sleeve wells 502) of wire harness. In at least one embodiment, thermal chokes may extend through openings at the bottoms of wells (e.g., through apertures 510) to seat with receptacles (e.g., sockets 512) of RF connectors. In at least one embodiment, thermal chokes may be electrically coupled to RF connectors. In at least one embodiment, a wire (e.g., wire 534) may be pre-soldered to RF connector. In at least one embodiment, wire may carry RF current to the connector. In at least one embodiment, RF connectors may comprise a threaded base (e.g., inner threaded portion 516) to which a threaded barrel may be attached. In at least one embodiment, threaded barrels may be tightened to secure RF connectors within wire harness.

In at least one embodiment, structures of various embodiments described herein can also be described as method of forming those structures, and method of operation of these structures.

The following examples are provided that illustrate at least one embodiment. The examples can be combined with other examples. As such, at least one embodiment can be combined with at least another embodiment without changing the scope of the invention.

Example 1 is a wafer chuck assembly, comprising a platen with one or more plasma electrodes; and a radio frequency (RF) assembly comprising at least one RF conductor electrically coupled to the one or more plasma electrodes, the at least one RF conductor comprises a rod with a rod tip coupled to the one or more plasma electrodes and a rod stem mechanically coupled to a thermal choke with a hollow interior, wherein the rod comprises a first electrically conductive material and has a first width and a first length; the thermal choke comprises a second electrically conductive material, and has a second width and a second length; and the second width is equal or greater than the first width.

Example 2 includes all features of example 1, wherein the rod comprises a rod stem that is inserted into a tubular body of the thermal choke, and wherein the the rod stem has a third length that is less than 10% of the first length.

Example 3 includes all features of example 1, wherein the rod further comprises an insertion stop on the stem portion, and wherein the insertion stop abuts a rim of the thermal choke.

Example 4 includes all features of example 1, wherein the first length is 20% to 50% of the second length.

Example 5 includes all features of example 1, wherein an RF assembly clamp is coupled to the at least one RF conductor, the RF assembly clamp comprising at least one retaining structure through which the at least one RF conductor extends, and wherein the at least one retaining structure is operable to pivotally engage the at least one RF conductor with the RF assembly clamp.

Example 6 includes all features of example 5, wherein the RF assembly clamp comprises a first portion and a second portion, wherein the at least one retaining structure is between the first portion and the second portion, wherein at least one first aperture extends through the first portion and is substantially coaxial with at least one second aperture that extends through the second portion, and wherein a third aperture extends through the at least one retaining structure and is substantially coaxial with the at least one first aperture and the at least one second aperture.

Example 7 includes all features of example 6, wherein the at least one retaining structure comprises a ball retainer pivotally engaged within a cavity of the RF assembly clamp, wherein the third aperture extends through the ball retainer; and wherein the at least one RF conductor is laterally constrained within the third aperture.

Example 8 includes all features of example 6, wherein the at least one retaining structure comprises a ring surrounding the third aperture, wherein the at least one RF conductor is laterally constrained within the third aperture, and wherein the at least one RF conductor is pivotally engaged within the third aperture.

Example 9 includes all features of example 8, wherein the ring comprises an elastomeric material, and wherein the elastomeric material is to deform by pivotal forces exerted by the at least one RF conductor.

Example 10 includes all features of example 1, wherein the thermal choke is bonded to the rod by a weld bond or a braze bond.

Example 11 includes all features of example 1, wherein the first electrically conductive material comprises nickel, iron, or copper.

Example 12 includes all features of example 1, wherein the second electrically conductive material comprises an alloy of nickel, copper, or iron.

Example 13 includes all features of example 1, wherein the thermal choke comprises a conductive coating on the outer wall.

Example 14 includes all features of example 13, wherein the conductive coating comprises gold, and wherein the conductive coating has a thickness of 20 microns or less.

Example 15 includes all features of example 1, wherein the thermal choke has a first end coupled to the rod and a second end coupled to an electrical connector, and wherein the electrical connector is electrically coupled to the thermal choke.

Example 16 includes all features of example 1, wherein the RF assembly further comprises a sleeve around the rod and thermal choke, wherein the sleeve comprises a non-conductive material, wherein the sleeve has a fourth length, and wherein the fourth length is equal to at least a portion of a sum of the first length and the second length.

Example 17 includes all features of example 16, wherein the non-conductive material comprises an oxide of aluminum, an oxide of silicon, or an organic polymer.

Example 18 includes all features of example 16, wherein the sleeve comprises a nose having a first wall thickness that is less than a second wall thickness of the sleeve.

Example 19 is a system, comprising a vacuum chamber; and a wafer chuck assembly within the vacuum chamber, wherein the wafer chuck assembly comprises a pedestal comprising a stem coupled to a platen, wherein the platen comprises at least one plasma discharge electrode; a column comprising an adapter tube coupled to the stem; and a radio frequency (RF) assembly, comprising at least one RF conductor comprising a rod mechanically coupled to a thermal choke and a sleeve that extends at least partially along a length of the at least one RF conductor; and a RF assembly clamp coupled to the at least one RF conductor, the RF assembly clamp comprising at least one retaining structure within a clamp body, wherein the at least one retaining structure comprises an aperture through which the at least one RF conductor extends, wherein the at least one retaining structure is operable to pivotally engage the at least one RF conductor with the clamp body, the at least one RF conductor extends though the column, and the at least one RF conductor is electrically coupled to the at least one plasma discharge electrode.

Example 20 includes all features of example 19, wherein a RF power source is electrically coupled to the at least one RF conductor.

Example 21 includes all features of example 19, wherein the platen comprises at least one counterbore on a lower surface of the platen, the at least one counterbore extends to the at least one plasma discharge electrode, and wherein a tip of the rod extends through the at least one counterbore to contact the at least one plasma discharge electrode.

Example 22 includes all features of example 19, wherein a column clamp assembly couples the stem of the pedestal to the adapter tube, and wherein the column clamp assembly comprises an upper clamp ring over a lower clamp ring.

Example 23 includes all features of example 19, wherein the RF assembly clamp is seated within the adapter tube, wherein the adapter tube comprises an inner wall comprising one or more contours.

Example 24 is a method for assembling a wafer chuck assembly, the method comprising receiving the wafer chuck assembly comprising a stem, the stem attached to a platen at a first end and comprising a lip at a second end, and an adapter tube comprising a flange at a third end and a base at a fourth end; seating a spacer plate into the second end of the stem, the spacer plate comprises one or more apertures; seating a radio frequency (RF) assembly into the base of the adapter tube, wherein the RF assembly comprises one or more RF conductors extending through apertures of an RF assembly clamp, wherein the RF assembly clamp has a unique orientation within the adapter tube, and wherein the one or more RF conductors extend through the spacer plate; and clamping the flange to an end of the stem.

Example 25 includes all features of example 24, further comprising coupling the RF assembly to a RF power source, wherein the RF power source is electrically coupled to an RF connector that is electrically coupled to the RF assembly.

Example 26 includes all features of example 24, wherein seating the RF assembly into the base of the adapter tube comprises seating the RF assembly into the RF assembly clamp, wherein the RF assembly clamp substantially constrains lateral motion of the one or more RF conductors, and wherein the one or more RF conductors are pivotably engaged within the RF assembly clamp.

Example 27 includes all features of example 24, wherein the one or more RF conductors comprise a rod comprising a tip, and wherein seating an RF assembly into the base of the adapter tube comprises contacting the tip to the platen.

Example 28 is a lower clamp ring, comprising a first surface and a second surface opposite the first surface and separated from the first surface by a thickness, wherein the first surface and the second surface extend between an outer radius and an inner radius; a circular groove within the second surface, wherein the circular groove has a width that extends partially between the outer radius and the inner radius, wherein the circular groove has an outboard sidewall and an inboard sidewall, respectively; the circular groove has a transverse wall extending between the inboard sidewall and the outboard sidewall, wherein the outboard sidewall extends inwardly from the second surface at an oblique angle toward the transverse wall, and wherein an intersection of the outboard sidewall and transverse wall is rounded; and a plurality of holes extends from the first surface into the circular groove,

Example 29 includes all features of example 28, wherein centers of the plurality of holes are coincident with a third radius that is greater than half of a distance between the first radius and the second radius, and wherein the plurality of holes is azimuthally spaced apart by about 60 degrees.

Example 30 includes all features of example 28, wherein the inboard sidewall comprises a flat portion.

Example 31 includes all features of example 28, comprising a first semiannular segment and a second semiannular segment, wherein the first semiannular segment comprises a first end and a second end, wherein the second semiannular segment comprises a third and a fourth end, and wherein the first end is adjacent to the third end, and wherein the second end is adjacent to the fourth end.

Example 32 includes all features of example 28, comprising a first quarter-annular segment, a second quarter-annular segment, a third quarter-annular segment and a fourth quarter-annular segment, wherein: the first quarter-annular segment comprises a first end and a second end; the second quarter-annular segment comprises a third end and a fourth end, wherein the third end is adjacent to the second end; the third quarter-annular segment comprises a fifth end and a sixth end, wherein the fifth end is adjacent to the fourth end; and the fourth quarter-annular segment comprises a seventh end and an eighth end, wherein the seventh end is adjacent to the sixth end and the eighth end is adjacent to the first end.

Example 33 is an upper clamp ring, comprising a first sidewall along an outer diameter; a second sidewall along an inner diameter, wherein a first surface extends between the outer diameter and the inner diameter, wherein the first surface is separated from a second surface by a thickness; and a plurality of through-holes extending through the thickness between the first surface and the second surface,

Example 34 includes all features of example 33, wherein centers of the plurality of through-holes are coincident with a radius that is less than half of a distance between the outer diameter and the inner diameter, and wherein the holes are azimuthally spaced by 60 degrees,

Example 35 includes all features of example 33, wherein the second sidewall comprises a beveled portion, wherein the beveled portion is chamfered at an oblique angle such that the first surface has a first surface area that is greater than a second surface area of the second surface.

Example 36 is a clamp assembly, comprising an upper clamp ring with at least one through-hole and a chamfer at a bottom surface adjacent to the inner radius of the upper clamp ring; a lower clamp ring with a top surface, a bottom surface, and at least one through-hole, wherein the bottom surface comprises a groove bound between an outer radius and an inner radius; wherein the upper clamp ring and the lower clamp ring are bolted via the through-holes of the upper and lower clamp rings by a bolt such that the bottom surface of the upper clamp ring is in direct contact with the top surface of the lower clamp ring.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the invention should be measured solely by reference to the claims that follow.

1. A wafer chuck assembly, comprising:
a platen with one or more plasma electrodes; and
a radio frequency (RF) assembly comprising at least one RF conductor electrically coupled to the one or more plasma electrodes, the at least one RF conductor comprises:
a rod with a rod tip coupled to the one or more plasma electrodes and a rod stem mechanically coupled to a thermal choke with a hollow interior, wherein:
the rod comprises a first electrically conductive material and has a first width and a first length;
the thermal choke comprises a second electrically conductive material, and has a second width and a second length; and
the second width is equal or greater than the first width.

2. The wafer chuck assembly of claim 1, wherein the rod stem is inserted into a tubular body of the thermal choke, and wherein the rod stem has a third length that is less than 10% of the first length.

3. The wafer chuck assembly of claim 1, wherein the rod further comprises an insertion stop on the rod stem, and wherein the insertion stop abuts a rim of the thermal choke.

4. The wafer chuck assembly of claim 1, wherein the first length is 20% to 50% of the second length.

5. The wafer chuck assembly of claim 1, wherein an RF assembly clamp is coupled to the at least one RF conductor, the RF assembly clamp comprising at least one retaining structure through which the at least one RF conductor extends, and wherein the at least one retaining structure is operable to pivotally engage the at least one RF conductor with the RF assembly clamp.

6. The wafer chuck assembly of claim 5, wherein the RF assembly clamp comprises a first portion and a second portion, wherein the at least one retaining structure is between the first portion and the second portion, wherein at least one first aperture extends through the first portion and is coaxial with at least one second aperture that extends through the second portion, and wherein a third aperture extends through the at least one retaining structure and is substantially coaxial with the at least one first aperture and the at least one second aperture.

7. The wafer chuck assembly of claim 6, wherein the at least one retaining structure comprises a ball retainer pivotally engaged within a cavity of the RF assembly clamp, wherein the third aperture extends through the ball retainer, and wherein the at least one RF conductor is laterally constrained within the third aperture.

8. The wafer chuck assembly of claim 6, wherein the at least one retaining structure comprises a ring surrounding the third aperture, wherein the at least one RF conductor is laterally constrained within the third aperture, and wherein the at least one RF conductor is pivotally engaged within the third aperture.

9. The wafer chuck assembly of claim 8, wherein the ring comprises an elastomeric material.

10. The wafer chuck assembly of claim 1, wherein the thermal choke is bonded to the rod.

11. The wafer chuck assembly of claim 1, wherein the first electrically conductive material comprises nickel, iron, or copper, and wherein the second electrically conductive material comprises an alloy of nickel, copper, or iron.

12. (canceled)

13. The wafer chuck assembly of claim 1, wherein the thermal choke comprises a conductive coating on an outer wall, and wherein the conductive coating comprises gold, and wherein the conductive coating has a thickness of 20 microns or less.

14. (canceled)

15. The wafer chuck assembly of claim 1, wherein the thermal choke has a first end coupled to the rod and a second end coupled to an electrical connector, and wherein the electrical connector is electrically coupled to the thermal choke.

16. The wafer chuck assembly of claim 1, wherein the RF assembly further comprises a sleeve around the rod and the thermal choke, wherein the sleeve comprises a non-conductive material, wherein the sleeve has a fourth length, wherein the fourth length is equal to at least a portion of a sum of the first length and the second length, and wherein the non-conductive material comprises an oxide of aluminum, an oxide of silicon, or an organic polymer.

17. (canceled)

18. The wafer chuck assembly of claim 16, wherein the sleeve comprises a nose having a first wall thickness that is less than a second wall thickness of the sleeve.

19. A system, comprising:
a vacuum chamber; and
a wafer chuck assembly within the vacuum chamber, wherein the wafer chuck assembly comprises:
a pedestal comprising a stem coupled to a platen, wherein the platen comprises at least one plasma discharge electrode;
an adapter tube coupled to the stem; and
a radio frequency (RF) assembly, comprising:
at least one RF conductor comprising a rod mechanically coupled to a thermal choke and a sleeve that extends at least partially along a length of the at least one RF conductor; and
a RF assembly clamp coupled to the at least one RF conductor, the RF assembly clamp comprising at least one retaining structure within a clamp body, wherein the at least one retaining structure comprises an aperture through which the at least one RF conductor extends, wherein:
the at least one retaining structure is operable to pivotally engage the at least one RF conductor with the clamp body,
the at least one RF conductor extends though the adapter tube and the stem, and
the at least one RF conductor is electrically coupled to the at least one plasma discharge electrode.

20. The system of claim 19, wherein a RF power source is electrically coupled to the at least one RF conductor, wherein the platen comprises at least one counterbore on a lower surface of the platen, the at least one counterbore extends to the at least one plasma discharge electrode, and wherein a tip of the rod extends through the at least one counterbore to contact the at least one plasma discharge electrode.

21. (canceled)

22. The system of claim 19, wherein a column clamp assembly couples the stem of the pedestal to the adapter tube, and wherein the column clamp assembly comprises an upper clamp ring over a lower clamp ring, wherein the RF assembly clamp is seated within the adapter tube, wherein the adapter tube comprises an inner wall comprising one or more contours.

23. (canceled)

24. A method for assembling a wafer chuck assembly, the method comprising:
receiving the wafer chuck assembly comprising a pedestal stem, the pedestal stem attached to a platen at a first end and comprising a lip at a second end, and an adapter tube comprising a flange at a third end and a base at a fourth end;
seating a spacer plate into the second end of the pedestal stem, the spacer plate comprises one or more apertures;
seating a radio frequency (RF) assembly into the base of the adapter tube, wherein the RF assembly comprises one or more RF conductors extending through apertures of an RF assembly clamp, wherein the RF assembly clamp has a unique orientation within the adapter tube, and wherein the one or more RF conductors extend through the spacer plate; and
clamping the flange to an end of the pedestal stem.

25. The method of claim 24, further comprising coupling the RF assembly to a RF power source, wherein the RF power source is electrically coupled to an RF connector that is electrically coupled to the RF assembly.

26-36. (canceled)
